(19) United States
(12) Patent Application Publication
(10) Pub. No.: US 2024/0247188 A1
(43) Pub. Date: Jul. 25, 2024

(54) SEMICONDUCTOR NANOPARTICLE, PRODUCTION METHOD THEREOF, AND ELECTROLUMINESCENT DEVICE INCLUDING THE SAME

(71) Applicant: Samsung Electronics Co., Ltd., Suwon-si (KR)

(72) Inventors: Yong Seok HAN, Suwon-si (KR); Ji Hyun MIN, Suwon-si (KR); Yuho WON, Suwon-si (KR); Jin A KIM, Suwon-si (KR); Hogeun CHANG, Suwon-si (KR); Hyundong HA, Suwon-si (KR)

(21) Appl. No.: 18/415,796

(22) Filed: Jan. 18, 2024

(30) Foreign Application Priority Data
Jan. 19, 2023 (KR) 10-2023-0008084

(51) Int. Cl. C09K 11/88; B82Y 20/00; B82Y 40/00; H10K 50/115

(52) U.S. Cl. CPC C09K 11/883; H10K 50/115; B82Y 20/00; B82Y 40/00

(57) ABSTRACT

A semiconductor nanoparticle, a production method, and an electroluminescent devices including the same, wherein the semiconductor nanoparticles include a zinc chalcogenide including zinc, selenium, and sulfur, the semiconductor nanoparticles do not include cadmium, the semiconductor nanoparticles exhibit a peak emission wavelength in a range of greater than or equal to about 455 nanometers (nm) and less than or equal to about 480 nm, in a photoluminescence spectroscopy analysis, the semiconductor nanoparticles exhibit an absolute quantum yield of greater than or equal to about 80% and a full width at half maximum of less than or equal to about 50 nm, and an average particle size of the semiconductor nanoparticles is greater than or equal to about 12 nm and less than or equal to about 50 nm.

### CROSS-REFERENCE TO RELATED APPLICATION

This application claims priority to and the benefit of Korean Patent Application No. 10-2023-0008084 filed in the Korean Intellectual Property Office on Jan. 19, 2023, and all the benefits accruing therefrom under 35 U.S.C. § 119, the content of which in its entirety is herein incorporated by reference.

### BACKGROUND

### 1. Field

The present disclosure relates to semiconductor nanoparticles and a device including the same.

### 2. Description of the Related Art

A semiconductor nanoparticle (e.g., semiconductor nanocrystal particle) may emit light. For example, a quantum dot including a semiconductor nanocrystal may exhibit a quantum confinement effect, showing, e.g., exhibiting, luminous properties. Light emission of the semiconductor nanoparticle may be generated, for example, when an electron in an excited state, by light excitation or by application of a voltage, moves, e.g., transitions, from a conduction band to a valence band. The semiconductor nanoparticle may be configured to emit light of a desired wavelength region by controlling a size, composition, or a combination thereof of the semiconductor nanoparticle.

A nanoparticle may be used in a light emitting device (e.g., an electroluminescent device) and a display device including the same.

### SUMMARY

An embodiment provides a blue light emitting semiconductor nanoparticle capable of exhibiting improved stability and luminous properties.

An embodiment provides a method of preparing the described semiconductor nanoparticles.

An embodiment provides a luminescent device for example, capable of emitting light, for example, by applying a voltage to a semiconductor nanoparticle (e.g., a quantum dot).

An embodiment provides a display device (e.g., a quantum dot light emitting diode (“QD-LED”) display) including a nanoparticle as a light emitting material in a blue pixel, a red pixel, a green pixel, or a combination thereof.

According to an embodiment, semiconductor nanoparticles include zinc, selenium, and sulfur,
wherein the semiconductor nanoparticles include a zinc chalcogenide,
the semiconductor nanoparticles do not include cadmium,
the semiconductor nanoparticles exhibit a peak emission wavelength (e.g., a photoluminescent or electroluminescent peak wavelength) in a range of greater than or equal to about 455 nanometers (nm) and less than or equal to about 480 nm,
in a photoluminescence spectroscopy analysis, the semiconductor nanoparticles exhibit an absolute quantum yield of greater than or equal to about 80% and a full width at half maximum of less than or equal to about 50 nm, and
an average particle size of the semiconductor nanoparticles is greater than or equal to about 12 nm and less than or equal to about 50 nm.

The peak emission wavelength of the semiconductor nanoparticles may be greater than or equal to about 455 nm, greater than or equal to about 458 nm, greater than or equal to about 460 nm, greater than or equal to about 463 nm, or greater than or equal to about 465 nm.

The peak emission wavelength of the semiconductor nanoparticles may be less than or equal to about 480 nm, less than or equal to about 478 nm, or less than or equal to about 475 nm.

The absolute quantum yield of the semiconductor nanoparticles may be greater than or equal to about 82%.

The absolute quantum yield of the semiconductor nanoparticles may be greater than or equal to about 84%.

The absolute quantum yield of the semiconductor nanoparticles may be greater than or equal to about 88%.

The absolute quantum yield of the semiconductor nanoparticles may be greater than or equal to about 90%.

The full width at half maximum of the semiconductor nanoparticles may be less than or equal to about 49 nm. The full width at half maximum of the semiconductor nanoparticles may be less than or equal to about 47 nm.

The semiconductor nanoparticles may have an average particle size of greater than or equal to about 12.5 nm, or greater than or equal to about 13.5 nm (e.g., as measured by an electron microscopy analysis).

The semiconductor nanoparticles may have an average particle size of less than or equal to about 45 nm, or less than or equal to about 30 nm.

The semiconductor nanoparticles may have an average particle size of greater than or equal to about 12 nm and less than or equal to about 14 nm and an absolute quantum yield of greater than or equal to about 90%. The semiconductor nanoparticles may have an average particle size of greater than 14 nm and an absolute quantum yield of greater than or equal to about 80%.

The semiconductor nanoparticles or the zinc chalcogenide may further include tellurium.

In the semiconductor nanoparticles, a mole ratio of selenium to a sum of selenium and sulfur (Se:(Se+S)) may be greater than or equal to about 0.57:1, or greater than or equal to about 0.58:1, and less than or equal to about 0.99:1.

In the semiconductor nanoparticles, a mole ratio of tellurium to sulfur may be greater than or equal to about 0.008:1, or greater than or equal to about 0.01:1. In the semiconductor nanoparticles, a mole ratio of tellurium to sulfur may be less than or equal to about 0.05:1.

The semiconductor nanoparticles may further include aluminum and an alkali metal.

The semiconductor nanoparticles may have an average aspect ratio of less than 1.19:1, as determined in a two-dimensional image obtained from electron microscope analysis.

The average aspect ratio of the semiconductor nanoparticles may be less than or equal to about 1.15:1.

The average aspect ratio of the semiconductor nanoparticles may be greater than or equal to about 1:1.

The semiconductor nanoparticles may have a core shell structure. The core shell structure may include a core including a first semiconductor nanocrystal and a semiconductor nanocrystal shell disposed on the core.

The first semiconductor nanocrystal may include (a first zinc chalcogenide including) zinc, selenium, and tellurium.

The semiconductor nanocrystal shell may be different from the first semiconductor nanocrystal and may include zinc, selenium, and sulfur.

The semiconductor nanocrystal shell may include a second semiconductor nanocrystal including a second zinc chalcogenide including zinc and selenium (or a middle shell layer including the second semiconductor nanocrystal) and a third semiconductor nanocrystal including a third zinc chalcogenide including zinc and sulfur (or an outer layer including the third semiconductor nanocrystal). The second zinc chalcogenide may have a composition different from that of the third zinc chalcogenide. The second zinc chalcogenide may further include or may not include sulfur. The third zinc chalcogenide may further include or may not include selenium.

The second semiconductor nanocrystal (or the middle shell layer) may be disposed between the first semiconductor nanocrystal (or the core) and the third semiconductor nanocrystal (or the outer layer).

A thickness of the second semiconductor nanocrystal (or the middle shell layer) may be greater than about 2.6 nm, greater than or equal to about 2.8 nm, greater than or equal to about 3 nm, or greater than or equal to about 3.5 nm.

A thickness of the second semiconductor nanocrystal (or the middle shell layer) may be less than or equal to about 6 nm, less than or equal to about 5.5 nm, or less than or equal to about 5 nm.

The thickness of the third semiconductor nanocrystal (or the outer layer) may be less than or equal to about 1.2 nm, less than or equal to about 1 nm, or less than or equal to about 0.8 nm.

The thickness of the third semiconductor nanocrystal (or the outer layer) may be greater than or equal to about 0.25 nm, or greater than or equal to about 0.5 nm.

In an embodiment, a method of producing the semiconductor nanoparticles includes:
contacting a zinc precursor and a chalcogen precursor at a reaction temperature in the presence of a first semiconductor nanocrystal including a first zinc chalcogenide including zinc, selenium, and optionally tellurium to prepare a semiconductor nanocrystal shell, wherein the chalcogen precursor includes a selenium precursor, a sulfur precursor, or a combination thereof (e.g., a selenium precursor and a sulfur precursor), and
wherein a reaction of the zinc precursor and the chalcogen precursor is carried out in the presence of an additive, wherein the additive includes an alkali metal compound and a metal halide (e.g., a metal chloride). The metal halide (e.g., the metal chloride) may include a zinc chloride, an aluminum chloride, or a combination thereof.

In the method of an embodiment, a reaction of a zinc precursor and a selenium precursor may be carried out in the presence of an alkali metal compound. In the method of an embodiment, the reaction between a zinc precursor and a sulfur precursor may be carried out in the presence of the additive (e.g., an alkali metal compound, a metal halide, or a combination thereof).

In the method of an embodiment, the additive may be added to a reaction system at the same time as or after the addition of the selenium precursor. In the method of an embodiment, the additive may be added to a reaction system at the same time or after the addition of the sulfur precursor.

In the method of an embodiment, the reaction temperature may be greater than or equal to about 335° C., greater than or equal to about 340° C., or greater than 340° C.

In an embodiment, a semiconductor nanoparticle includes a core including a first semiconductor nanocrystal including a first zinc chalcogenide including zinc, selenium, and tellurium; and a semiconductor nanocrystal shell including a middle shell layer including a second semiconductor nanocrystal including a second zinc chalcogenide including zinc and selenium disposed on the core, and an outer shell layer including a third semiconductor nanocrystal including a third zinc chalcogenide including zinc and sulfur disposed on the middle shell layer, wherein a particle size of the semiconductor nanoparticle is greater than or equal to about 12 nanometers and less than or equal to about 50 nanometers, wherein a thickness of the second semiconductor nanocrystal (or the middle shell layer) is greater than or equal to about 3.5 nanometers, wherein a thickness of the third semiconductor nanocrystal (or the outer shell layer) is less than or equal to about 1 nanometer, and wherein an aspect ratio of the semiconductor nanoparticle is less than or equal to about 1.15:1. The middle shell layer may be disposed between the core and the outer shell layer.

In an embodiment, an electroluminescent device includes:
a first electrode and a second electrode spaced apart from each other (e.g., facing each other), and
an emission layer disposed between the first electrode and the second electrode, the emission layer including a first semiconductor nanoparticle including zinc, selenium, and sulfur, wherein the first semiconductor nanoparticle includes a zinc chalcogenide, and the first semiconductor nanoparticle does not include cadmium, wherein the first semiconductor nanoparticle has a particle size of greater than or equal to about 12 nm and less than or equal to about 50 nm, the electroluminescent device or the light emitting layer is configured to emit blue light, and the electroluminescent device exhibits a maximum external quantum efficiency of greater than or equal to about 10% and a maximum luminance of greater than or equal to about 100,000 candelas per square meter (cd/m²).

The blue light may have a peak emission wavelength of greater than or equal to about 460 nm, or greater than or equal to about 465 nm and less than or equal to about 480 nm, or less than or equal to about 475 nm.

The emission layer may be configured to emit light of a peak emission wavelength that is greater than or equal to 455 nm and less than or equal to about 480 nm, or greater than or equal to 455 nm and less than 480 nm, for example, as, e.g., when, irradiated with incident light.

The first semiconductor nanoparticle may have an (average) size of greater than or equal to about 12.5 nm and less than or equal to about 50 nm.

The first semiconductor nanoparticle may include the semiconductor nanoparticles described herein.

The light emitting layer includes a first light emitting layer and a second light emitting layer disposed between the first light emitting layer and the first electrode, the first light emitting layer including the first semiconductor nanoparticle, the second light emitting layer including a second semiconductor nanoparticle including zinc, selenium, and sulfur, and a particle size (or an average particle size) of the first semiconductor nanoparticle may be greater than a particle size (or an average particle size) of the second semiconductor nanoparticle.

The first electrode may be an anode and the second electrode may be a cathode.

The electroluminescent device may have a maximum external quantum efficiency of greater than or equal to about 11%.

The electroluminescent device may include a charge auxiliary layer between the first electrode and the light emitting layer, between the second electrode and the light emitting layer, or between the first electrode and the light emitting layer and between the second electrode and the light emitting layer.

The charge auxiliary layer may include a hole auxiliary layer including an organic compound, an electron auxiliary layer including metal oxide nanoparticles, or a combination thereof.

In an embodiment, the display device or the electronic device may include the electroluminescent device or the semiconductor nanoparticle.

The display device or the electronic device may include a portable terminal device, a monitor, a notebook computer, a television, an electronic board, a camera, or an electronic component.

According to an embodiment, it is possible to obtain a semiconductor nanoparticle that emits blue light in a desired wavelength range while exhibiting improved optical properties (for example, an increased light emitting efficiency and a stability). The semiconductor nanoparticle of an embodiment may be applied to, e.g., used in, a light emitting device. The electroluminescent device including the semiconductor nanoparticle may exhibit a relatively increased external quantum efficiency and an increased maximum luminance.

### BRIEF DESCRIPTION OF THE DRAWINGS

The above and other advantages and features of this disclosure will become more apparent by describing in further detail exemplary embodiments thereof with reference to the accompanying drawings, in which:

FIG. 1 is a schematic cross-sectional view of an embodiment of a quantum dot light emitting diode (“QD-LED”) device;

FIG. 2 is a schematic cross-sectional view of an embodiment of a QD-LED device; and

FIG. 3 is a schematic cross-sectional view of an embodiment of a QD-LED device.

### DETAILED DESCRIPTION

Hereinafter, example embodiments of the present disclosure will be described in detail so that a person skilled in the art would understand the same. This disclosure may, however, be embodied in many different forms and is not construed as limited to the example embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer, or section from another element, component, region, layer, or section. Thus, “a first element,” “component,” “region,” “layer,” or “section” discussed below could be termed a second element, component, region, layer, or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10% or 5% of the stated value.

Relative terms, such as “downward,” “lower,” or “bottom,” and “upward,” “upper”, or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

As used herein, values of a work function, a conduction band, or a lowest unoccupied molecular orbital (“LUMO”) (or valence band, or highest occupied molecular orbital (“HOMO”)) energy level is expressed as an absolute value from a vacuum level. In addition, when the work function or the energy level is referred to be “deep,” “high” or “large,” the work function or the energy level has a large absolute value based on “0 electron volts (eV)” of the vacuum level, while when the work function or the energy level is referred to be “shallow,” “low,” or “small,” the work function or energy level has a small absolute value based on “0 eV” of the vacuum level. In an aspect, work function herein refers to a minimum energy to remove an electron from e.g., a solid metal (e.g., a metal surface) to vacuum (e.g., immediately outside the solid surface).

As used herein, the average (value) may be mean or median. In an embodiment, the average (value) may be a mean value.

As used herein, the term “peak emission wavelength” is the wavelength at which a given emission spectrum of the light reaches its maximum.

As used herein, the term “Group” may refer to a group of Periodic Table.

As used herein, “Group III” may refer to Group IIIA and Group IIIB, and examples of Group III metal may be Al, In, Ga, and TI, but are not limited thereto.

As used herein, “Group V” may refer to Group VA, and examples may include nitrogen, phosphorus, arsenic, antimony, and bismuth, but are not limited thereto.

As used herein, when a definition is not otherwise provided, “substituted” refers to replacement of hydrogen of a compound, a group, or a moiety by a C1 to C30 alkyl group, a C2 to C30 alkenyl group, a C2 to C30 alkynyl group, a C2 to C30 epoxy group, a C2 to C30 alkyl ester group, a C3 to C30 alkenyl ester group (e.g., an acrylate group, methacrylate group), a C6 to C30 aryl group, a C7 to C30 alkylaryl group, a C1 to C30 alkoxy group, a C1 to C30 heteroalkyl group, a C3 to C40 heteroaryl group, a C3 to C30 heteroarylalkyl group, a C3 to C30 heteroalkylaryl group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a thiocyanate group (—SCN), a cyano group (—CN), an amino group (—NRR′ wherein R and R′ are independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O)OR, wherein R is a C1 to C6 alkyl group or a C6 to C12 aryl group), a carboxyl group (—COOH) or a salt thereof (—C(═O)OM, wherein M is an organic or inorganic cation), a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), or a combination thereof.

As used herein, when a definition is not otherwise provided, “hydrocarbon” or “hydrocarbon group” refers to a compound or a group including carbon and hydrogen (e.g., alkyl, alkenyl, alkynyl, or aryl group). The hydrocarbon group may be a monovalent group or a group having a valence of greater than one formed by removal of one or more hydrogen atoms from an alkane, an alkene, an alkyne, or an arene. In the hydrocarbon or hydrocarbon group, a, e.g., at least one, methylene may be replaced by an oxide moiety, a carbonyl moiety, an ester moiety, —NH—, or a combination thereof. Unless otherwise stated to the contrary, the hydrocarbon or the hydrocarbon group (alkyl, alkenyl, alkynyl, or aryl) may have 1 to 60, 2 to 32, 3 to 24, or 4 to 12 carbon atoms.

As used herein, when a definition is not otherwise provided, “alkyl” refers to a linear or branched saturated monovalent hydrocarbon group (methyl, ethyl hexyl, etc.). In an embodiment, an alkyl group may have from 1 to 50 carbon atoms, or 1 to 18 carbon atoms, or 1 to 12 carbon atoms.

As used herein, when a definition is not otherwise provided, “alkenyl” refers to a linear or branched monovalent hydrocarbon group having a carbon-carbon double bond. In an embodiment, an alkenyl group may have from 2 to 50 carbon atoms, or 2 to 18 carbon atoms, or 2 to 12 carbon atoms.

As used herein, when a definition is not otherwise provided, “alkynyl” refers to a linear or branched monovalent hydrocarbon group having a carbon-carbon triple bond. In an embodiment, an alkynyl group may have from 2 to 50 carbon atoms, or 2 to 18 carbon atoms, or 2 to 12 carbon atoms.

As used herein, when a definition is not otherwise provided, “aryl” refers to a group having a carbocyclic aromatic system. When the aryl group includes a plurality of rings, the plurality of rings may be fused to each other. Examples include a phenyl group and a naphthyl group. In an embodiment, an aryl group may have 6 to 50 carbon atoms, or 6 to 18 carbon atoms, or 6 to 12 carbon atoms.

As used herein, when a definition is not otherwise provided, “hetero” refers to inclusion of 1 to 3 heteroatoms, e.g., N, O, P, Si, B, Se, Ge, Te, S, or a combination thereof.

As used herein, “heteroaryl” refers to an aromatic system having N, O, P, Si, B, Se, Ge, Te, S, or a combination thereof as a ring forming atom. Examples of heteroaryl groups include a pyridinyl group, a pyrimidinyl group, a pyrazinyl group, a pyridazinyl group, a triazinyl group, a quinolinyl group, and an isoquinolinyl group. When the heteroaryl group includes a plurality of rings, the plurality of rings may be fused to each other. In an embodiment, the heteroaryl group may have 3 to 50 carbon atoms, or 6 to 18 carbon atoms, or 6 to 12 carbon atoms.

As used herein, when a definition is not otherwise provided, “alkoxy” refers to an alkyl group linked to oxygen (e.g., alkyl-O—) for example, a methoxy group, an ethoxy group, or a sec-butyloxy group.

The term “cycloalkyl group” as used herein refers to a monovalent monocyclic saturated hydrocarbon group. Examples thereof include a cyclopropyl group, a cyclobutyl group, a cyclopentyl group, a cyclohexyl group, and a cycloheptyl group. In an embodiment, the cycloalkyl group may have 3 to 50 carbon atoms, or 3 to 18 carbon atoms, or 3 to 12 carbon atoms.

The term “heterocycloalkyl group” as used herein refers to a monovalent monocyclic saturated group including N, O, P, Si, B, Se, Ge, Te, S, or a combination thereof as a ring-forming atom in addition to the carbon atoms that are ring-forming atoms. Examples thereof include a tetrahydrofuranyl group and a tetrahydrothiophenyl group. In an embodiment, the heterocycloalkyl group may have 2 to 50 carbon atoms, or 2 to 18 carbon atoms, or 2 to 12 carbon atoms.

The term “cycloalkenyl group” as used herein refers to a monovalent monocyclic hydrocarbon group that has a, e.g., at least one, carbon-carbon double bond in its ring, wherein the molecular structure as a whole is non-aromatic. Examples thereof include a cyclopentenyl group, a cyclohexenyl group, and a cycloheptenyl group. In an embodiment, the cycloalkenyl group may have 3 to 50 carbon atoms, or 3 to 18 carbon atoms, or 3 to 12 carbon atoms.

The term “heterocycloalkenyl group” as used herein refers to a monovalent monocyclic group including N, O, P, Si, B, Se, Ge, Te, S, or a combination thereof as a ring-forming atom, and a, e.g., at least one, double bond in its ring, wherein the molecular structure as a whole is non-aromatic. Examples of the heterocycloalkenyl group include a 2,3-dihydrofuranyl group and a 2,3-dihydrothiophenyl group. In an embodiment, the heterocycloalkenyl group may have 2 to 50 carbon atoms, or 2 to 18 carbon atoms, or 2 to 12 carbon atoms.

The term “arylalkyl group” refers to an alkyl group substituted with an aryl group. An example of an arylalkyl group is a benzyl group (i.e., CH₂-phenyl).

The term “alkylaryl group” refers to an aryl group substituted with an alkyl group. An example of an alkylaryl group is a toluyl group.

As used herein, when a definition is not otherwise provided, “amine” is a compound represented by NR₃, wherein each R is independently hydrogen, a C1-C12 alkyl group, a C7-C20 alkylaryl group, a C7-C20 arylalkyl group, or a C6-C18 aryl group.

As used herein, the expression “not including cadmium (or other harmful heavy metal)” means that a concentration of cadmium (or another heavy metal deemed harmful) may be less than or equal to about 100 parts per million by weight (“ppmw”), less than or equal to about 50 ppmw, less than or equal to about ppmw, less than or equal to about 1 ppmw, less than or equal to about 0.1 ppmw, less than or equal to about 0.01 ppmw, or zero. In an embodiment, substantially no amount of cadmium (or other toxic heavy metal) may be present or, if present, an amount of cadmium (or other heavy metal) may be less than or equal to a detection limit or as an impurity level of a given analysis tool (e.g., an inductively coupled plasma atomic emission spectroscopy instrument).

Unless mentioned to the contrary, a numerical range recited herein is inclusive. Unless mentioned to the contrary, a numerical range recited herein includes any real number within the endpoints of the stated range and includes the endpoints thereof. In this specification, a numerical endpoint or an upper or lower limit value (e.g., recited either as a “greater than or equal to value” “at least value” or a “less than or equal to value” or recited with “from” or “to”) may be used to form a numerical range of a given feature. In other words, the upper and lower endpoints set forth for various numerical values may be independently combined to provide a range. “About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, 5%, 3%, or 1% of the stated value.

As used herein, a nanoparticle is a structure having a, e.g., at least one, region or characteristic dimension with a nanoscale dimension. In an embodiment, a dimension (or an average dimension) of the nanostructure is less than or equal to about 500 nanometers (nm), less than or equal to about 300 nm, less than or equal to about 250 nm, less than or equal to about 150 nm, less than or equal to about 100 nm, less than or equal to about 50 nm, or less than or equal to about nm, and may be greater than about 0.1 nm or greater than about 1 nm. In an embodiment, the nanoparticle may have any suitable shape.

The nanoparticle (e.g., a semiconductor nanoparticle or a metal oxide nanoparticle) may include a nanowire, a nanorod, a nanotube, a branched nanostructure, a nanotetrapod, a nanotripod, a nanobipod, a nanodot, a multi-pod type shape such as at least two pods, or the like and is not limited thereto. The nanoparticle can be, e.g., substantially crystalline, substantially monocrystalline, polycrystalline, (for example, at least partially) amorphous, or a combination thereof.

In an embodiment, a semiconductor nanoparticle such as a quantum dot may exhibit quantum confinement or exciton confinement. As used herein, the term “quantum dot” or “semiconductor nanostructure” is not limited in a shape thereof unless otherwise defined. A semiconductor nanoparticle or a quantum dot may have a size smaller than a Bohr excitation diameter for a bulk crystal material having an identical composition and may exhibit a quantum confinement effect. The semiconductor nanoparticle or the quantum dot may emit light corresponding to a bandgap energy thereof by controlling a size of a nanocrystal acting as an emission center.

As used herein, the term “T50” is a time (hours, hr) the brightness (e.g., luminance) of a given device decreases to 50% of the initial brightness (100%) as, e.g., when, the given device is started to be driven, e.g., operated, at a predetermined initial brightness.

As used herein, the term “T90” is a time (hr) the brightness (e.g., luminance) of a given device decreases to 90% of the initial brightness (100%) as the given device is started to be driven at a predetermined initial brightness.

As used herein, the phrase “external quantum efficiency (“EQE”)” is a ratio of the number of photons emitted from a light-emitting diode (“LED”) to the number of electrons passing through the device and can be a measurement as to how efficiently a given device converts electrons to photons and allows the photons to escape. The EQE may be determined by the following equation:

EQE=(efficiency of injection)×((solid-state)quantum yield)×(efficiency of extraction)
wherein the efficiency of injection is a proportion of electrons passing through the device that are injected into the active region, the quantum yield is a proportion of all electron-hole recombinations in the active region that are radiative and produce photons, and the efficiency of extraction is a proportion of photons generated in the active region that escape from the given device.

As used herein, a maximum EQE is a greatest value of the EQE.

As used herein, a maximum luminance is the highest value of luminance for a given device.

As used herein, the phrase, quantum efficiency, may be used interchangeably with the phrase, quantum yield. In an embodiment, the quantum efficiency may be a relative quantum yield or an absolute quantum yield, for example, which can be readily measured by any suitable, e.g., commercially available, equipment. The quantum efficiency (or quantum yield) may be measured in a solution state or a solid state (in a composite). In an embodiment, “quantum yield (or quantum efficiency)” may be a ratio of photons emitted to photons absorbed, e.g., by a nanostructure or population of nanostructures. In an embodiment, the quantum efficiency may be determined by any suitable method. For example, there may be two methods for measuring the fluorescence quantum yield or efficiency: the absolute method and the relative method.

The absolute method directly obtains the quantum yield by detecting all sample fluorescence through the use of an integrating sphere. In the relative method, the fluorescence intensity of a standard sample (e.g., a standard dye) may be compared with the fluorescence intensity of an unknown sample to calculate the quantum yield of the unknown sample. Coumarin 153, Coumarin 545, Rhodamine 101 inner salt, Anthracene, and Rhodamine 6G may be used as standard dye, depending on the photoluminescence (“PL”) wavelengths thereof, but are not limited thereto.

A bandgap energy of a semiconductor nanoparticle may vary with a size and a composition of a nanocrystal. For example, as a size of the semiconductor nanoparticle increases, the bandgap energy of the semiconductor nanoparticle may become smaller, e.g., narrower, and the semiconductor nanoparticle may emit light having an increased wavelength. A semiconductor nanocrystal may be used as a light-emitting material in various fields such as in, a display device, an energy device, or a bio light-emitting device.

In the light-emitting layer, a quantum dot capable of exhibiting a practically applicable level of an electroluminescent property may include a harmful heavy metal such as cadmium (Cd), lead, mercury, or a combination thereof. Accordingly, it is desirable to provide a light-emitting device or a display device having a light-emitting layer substantially free of the harmful heavy metal. In QD-LEDs, satisfactory electroluminescent properties may be based on a cadmium-based (i.e., cadmium-containing) LED, and there is room for improvement in a QD-LED device using an environmentally-friendly quantum dot and, for example, emitting blue light that does not include cadmium or other harmful heavy metals.

The semiconductor nanoparticle according to an embodiment is environmentally friendly, may emit blue light of a desired wavelength with improved luminous efficiency, and may exhibit an improved stability to the external environment. The electroluminescent device according to an embodiment includes the semiconductor nanoparticle and is a self-emissive light emitting device configured to emit a desired light by applying a voltage with or without a separate light source. The light emitting device and the display device of an embodiment are desired from an environmental point of view.

In an embodiment, the semiconductor nanoparticle includes zinc, selenium, and sulfur. The semiconductor nanoparticle includes a zinc chalcogenide, and does not contain cadmium, and the semiconductor nanoparticle exhibits a peak emission wavelength (e.g., a maximum photoluminescence peak wavelength) in a range of greater than or equal to 458 nm and less than or equal to about 480 nm, or greater than or equal to 458 nm and less than 480 nm, and the semiconductor nanoparticle exhibits an absolute quantum yield of greater than or equal to about 80% and a full width at half maximum of less than or equal to about 50 nm in a (photo- or electro-) luminescence spectroscopy, and the semiconductor nanoparticle has a particle size (or an average particle size, hereinafter, “size”) of greater than or equal to about 11.5 nm, or greater than or equal to about 12 nm, and less than or equal to about 50 nm. An embodiment relates to an electronic device (an electroluminescent device) including the semiconductor nanoparticle (e.g., in the light emitting layer).

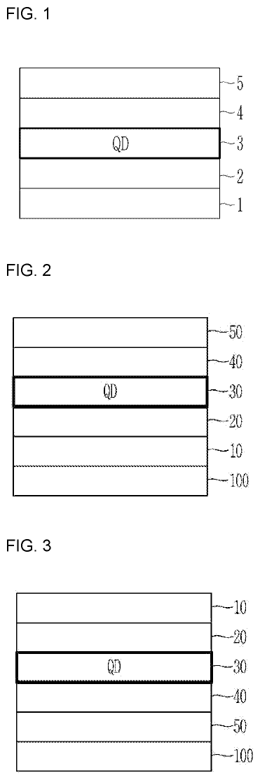

In an embodiment, an electroluminescent device includes a first electrode 1 and a second electrode 5 spaced apart from each other (e.g., each having a surface opposite the other, i.e., each with a surface facing each other); and alight emitting layer 3 disposed between the first electrode 1 and the second electrode 5. (See FIG. 1). The light emitting layer may not contain cadmium. The first electrode may include an anode, and the second electrode may include a cathode. The first electrode may include a cathode and the second electrode may include an anode. In an embodiment, the electroluminescent device may further include a hole auxiliary layer 2 between the light emitting layer and the first electrode. In an embodiment, the electroluminescent device may further include an electron auxiliary layer 4 between the light emitting layer and the second electrode.

In the electroluminescent device of an embodiment, the first electrode 10 or the second electrode 50 may be disposed on a (transparent) substrate 100. The transparent substrate may be a light extraction surface. (See FIGS. 2 and 3).

Referring to FIG. 2 and FIG. 3, in alight emitting device of an embodiment, a light emitting layer 30 may be disposed between a first electrode (e.g., anode) and a second electrode (e.g., cathode) 50. The cathode 50 may include an electron injection conductor. The anode 10 may include a hole injection conductor. The work functions of the electron/hole injection conductors included in the cathode and the anode may be appropriately adjusted and are not particularly limited. For example, the cathode may have a small work function and the anode may have a relatively large work function, or vice versa.

The electron/hole injection conductors may include a metal-based material (e.g., a metal, a metal compound, an alloy, or a combination thereof) (e.g., aluminum, magnesium, tungsten, nickel, cobalt, platinum, palladium, calcium, LiF, etc.), a metal oxide such as gallium indium oxide or indium tin oxide (ITO), or a conductive polymer (e.g., having a relatively high work function) such as polyethylene dioxythiophene, but are not limited thereto.

The first electrode, the second electrode, or a combination thereof may be a light-transmitting electrode or a transparent electrode. In an embodiment, both the first electrode and the second electrode may be a light-transmitting electrode. The electrode(s) may be patterned. The first electrode, the second electrode, or a combination thereof may be disposed on a (e.g., insulating) substrate. The substrate may be optically transparent (e.g., may have a light transmittance of greater than or equal to about 50%, greater than or equal to about 60%, greater than or equal to about 70%, greater than or equal to about 80%, greater than or equal to about 85%, or greater than or equal to about 90% and, for example, less than or equal to about 99%, or less than or equal to about 95%). The substrate may include a region for a blue pixel, a region for a red pixel, a region for a green pixel, or a combination thereof. A thin film transistor may be disposed in each region of the substrate, and one of a source electrode and a drain electrode of the thin film transistor may be electrically connected to the first electrode or the second electrode.

The light-transmitting electrode may be disposed on a (e.g., insulating) transparent substrate. The substrate may be a rigid or a flexible substrate. The substrate may include a plastic or organic material such as a polymer, an inorganic material such as a glass, or a metal.

The light-transmitting electrode may have a light transmittance of greater than or equal to about 50%, greater than or equal to about 60%, greater than or equal to about 70%, greater than or equal to about 80%, or greater than or equal to about 90%, for example, from about 80% to about 100%, from about 85% to about 95%, or a combination thereof.

The light-transmitting electrode may be made of, for example, a transparent conductor such as indium tin oxide (“ITO”) or indium zinc oxide (“IZO”), gallium indium tin oxide, zinc indium tin oxide, titanium nitride, polyaniline, LiF/Mg:Ag, or the like, or a metal thin film of a single layer or a plurality of layers, but is not limited thereto. If one of the first electrode and the second electrode is an opaque electrode, the opaque electrode may be made of an opaque conductor such as aluminum (AI), a lithium-aluminum (Li:Al) alloy, a magnesium-silver (Mg:Ag) alloy, or a lithium fluoride-aluminum (LiF:Al) compound. In the case of the alloy electrode, the ratio between each material may be appropriately adjusted, for example, in the range of from about 1:0.1 to about 1:10, from about 1:0.2 to about 1:5, from about 1:0.3 to about 1:3, or a combination thereof.

The multilayer electrode may include, for example, a translucent conductive material such as an indium tin oxide, an opaque conductive material such as an aluminum (or a reflective electrode material), or a combination thereof. In an embodiment, the electrode (e.g., an anode or a cathode) may have a structure in which an opaque conductive material (or a reflective electrode material layer) is disposed between translucent conductive materials (e.g., translucent conductive material layers). In an embodiment, the electrode (an anode or a cathode) may have a structure in which a translucent conductive material (e.g., a translucent conductive material layer) is disposed between opaque conductive materials (or reflective electrode materials).

As a voltage is applied between the first electrode and the second electrode, the light emitting layer may emit light upward, downward, or a combination thereof by an electric field, and the light traveling to the reflective electrode may be reflected and emitted in an opposite direction. In an embodiment, the light may be emitted toward the cathode. In an embodiment, light may be emitted toward the anode.

A thickness of each of the electrodes (the first electrode, the second electrode, or each of the first electrode and the second electrode) is not particularly limited and may be appropriately selected taking into consideration device efficiency. For example, the thickness of the electrode may be greater than or equal to about 5 nm, greater than or equal to about 10 nm, greater than or equal to about 20 nm, greater than or equal to about 30 nm, greater than or equal to about 40 nm, or greater than or equal to about 50 nm. For example, the thickness of the electrode may be less than or equal to about 100 micrometers (μm), less than or equal to about 90 μm, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 10 μm, less than or equal to about 1 μm, less than or equal to about 900 nm, less than or equal to about 500 nm, or less than or equal to about 100 nm.

The light emitting layer 30 disposed between the first electrode 1 and the second electrode 5 (e.g., the anode 10 and the cathode 50) may include a semiconductor nanoparticle (e.g., a blue light emitting nanoparticle, and a red light emitting nanoparticle, a green light emitting nanoparticle, or a combination thereof). The light emitting layer may include one or more (e.g., 2 or more or 3 or more and 10 or less) monolayers of a plurality of nanostructures.

The light emitting layer may be patterned. In an embodiment, the patterned light emitting layer may include a blue light emitting layer disposed in the blue pixel. In an embodiment, the light emitting layer may further include a red light emitting layer disposed in the red pixel, a green light emitting layer disposed in the green pixel, or a red light emitting layer disposed in the red pixel and a green light emitting layer disposed in the green pixel. Each of the (e.g., red, green, or blue) light emitting layers may be (e.g., optically) separated from an adjacent light emitting layer by a partition wall. In an embodiment, partition walls such as black matrices may be disposed between the red light emitting layer(s), the green light emitting layer(s), and the blue light emitting layer(s). The red light emitting layer, the green light emitting layer, and the blue light emitting layer may be optically isolated from each other.

The light emitting layer or the semiconductor nanoparticles may not include cadmium. The light emitting layer or the semiconductor nanoparticles may not include lead, mercury, or a combination thereof.

The semiconductor nanoparticle included in the emission layer 3 or 30 include zinc, selenium, and sulfur. An embodiment provides the semiconductor nanoparticle or a population thereof.

The semiconductor nanoparticle includes zinc, selenium, and sulfur. The semiconductor nanoparticle includes a zinc chalcogenide that includes zinc; and a chalcogen element (e.g., selenium, tellurium, sulfur, or a combination thereof). The semiconductor nanoparticle or the zinc chalcogenide may further include tellurium. The semiconductor nanoparticle may not include a Group III-V compound including indium and phosphorus. In an example, the semiconductor nanoparticle may not include an indium phosphide, an indium gallium phosphide, an indium zinc phosphide, or a combination thereof. The semiconductor nanoparticle exhibits a peak emission wavelength, for example, a photoluminescent peak wavelength, of greater than or equal to about 455 nm and less than or equal to about 480 nm, or greater than or equal to about 455 nm and less than 480 nm, and the semiconductor nanoparticle may be configured to exhibit an absolute quantum yield of greater than or equal to about 80% and a full width at half maximum of less than or equal to about 50 nm, for example, in a photoluminescence spectroscopy analysis. The semiconductor nanoparticle may have a particle size (e.g., an average particle size) of greater than or equal to about 11.5 nm, greater than or equal to about 12 nm and less than or equal to about 50 nm, or less than or equal to about 30 nm.

A cadmium free semiconductor nanoparticle configured to emit blue light may have a relatively more room for improvement in terms of an optical property and stability than a cadmium free semiconductor nanoparticle that emits green light or red light. Recently, there has been a study on a cadmium free semiconductor nanoparticle emitting blue light, including a zinc chalcogenide as a light emission center. The semiconductor nanocrystal containing a zinc chalcogenide (e.g., a zinc selenide further including tellurium) may serve as a light emission center that emits blue light. A semiconductor nanocrystal shell (e.g., including a zinc selenide, a zinc sulfide, or a combination thereof) having a composition different from that of the zinc chalcogenide on such a zinc chalcogenide-containing semiconductor nanocrystal may be provided, for example, to increase a luminous efficiency. The present inventors have found that, unlike an indium phosphide-based core-shell semiconductor nanoparticle having a type I structure, the technical effects (e.g., improving luminous efficiency and stability) by introducing a zinc chalcogenide semiconductor nanocrystal shell may be limited. A nanoparticle containing a zinc chalcogenide semiconductor nanocrystal core and a zinc chalcogenide semiconductor nanocrystal shell may have a type II structure and such a structure may have a relatively low quantum confinement, which may limit the improvement of efficiency and stability due to the introduction of the shell. In addition, the present inventors have found that a cadmium free semiconductor nanoparticle with blue light emission may have a difficulty in exhibiting desired level of electroluminescence properties (e.g., a high luminous efficiency and a high luminance) when applied to, e.g., used in, an emission layer in an actual device (e.g., an electroluminescence device), even if it can exhibit an improved level of optical properties in a solution state. Without wishing to be bound by a specific theory, it is believed that improvement in terms of stability (e.g., stability to the surrounding environment) of a cadmium free semiconductor particle with blue light emission with high efficiency may be desired. Moreover, there still remains a technical demand for a semiconductor nanoparticle that can emit blue light of a relatively longer-wavelength region, it is also desired to develop a semiconductor nanoparticle that can emit blue light in such a long-wavelength region with a desired level of luminous efficiency.

The semiconductor nanoparticle according to an embodiment may be configured to emit blue light of a desired peak emission wavelength and may achieve an improved level of optical properties together with a relatively increased (average) size as described herein.

In an embodiment, the first semiconductor nanocrystal or the core may include (e.g., a zinc chalcogenide including) zinc and selenium, and optionally further include tellurium. A size (or an average size) of the core(s) may be greater than or equal to about 2 nm, greater than or equal to about 3 nm, or greater than or equal to about 4 nm. A size (or an average size) of the core may be less than or equal to about 6 nm, or less than or equal to about 5 nm. The first semiconductor nanocrystal may include ZnTeₓSe₁₋ₓ (wherein x is greater than 0, greater than or equal to about 0.001, greater than or equal to about 0.003, greater than or equal to about 0.005, greater than or equal to about 0.007, greater than or equal to about 0.009, greater than or equal to about 0.01, greater than or equal to about 0.03, greater than or equal to about 0.05, greater than or equal to about 0.09 and less than 0.1, or less than or equal to about 0.04). The core may or may not contain sulfur.

The semiconductor nanocrystal shell may have a composition different from that of the first semiconductor nanocrystal. In the semiconductor nanoparticle, the semiconductor nanocrystal shell or the zinc chalcogenide included therein may include zinc, selenium, and sulfur. The shell may include or may not include tellurium. The shell (or each layer in the multilayer shell described herein) may be a gradient alloy having a composition that changes in the radial direction. In an embodiment, the amount of the sulfur in the semiconductor nanocrystal shell may increase toward a surface of the semiconductor nanoparticle. In the shell, the amount of sulfur may have a concentration gradient that increases as the distance from the core increases.

The shell may be a multi-layer shell including a plurality of layers. In the multilayer shell, adjacent layers may include semiconductor materials having different compositions. The multilayer shell may include a middle shell layer disposed on the core (e.g., directly above or on the core) and an outer shell layer disposed on the middle shell layer. The second semiconductor nanocrystal (or the middle shell layer) may be disposed between the first semiconductor nanocrystal (or the core) and the third semiconductor nanocrystal (or the outer layer).

In an embodiment, the semiconductor nanocrystal shell may include a second semiconductor nanocrystal including a second zinc chalcogenide including zinc and selenium (or a middle shell layer including the second semiconductor nanocrystal) and a third semiconductor nanocrystal including a third zinc chalcogenide including zinc and sulfur (or an outer layer including the third semiconductor nanocrystal). The second zinc chalcogenide may have a composition different from that of the third zinc chalcogenide. The outer layer may be referred to as “outer shell layer.”

The middle shell layer or the second semiconductor nanocrystal may include zinc, selenium, and optionally sulfur. The second zinc chalcogenide may include or may not include sulfur. The middle shell layer or the second semiconductor nanocrystal may include ZnSe, ZnSeS, or a combination thereof. The outer shell layer or the third semiconductor nanocrystal may include zinc, sulfur, and optionally selenium. The outer shell layer or the third semiconductor nanocrystal may include ZnS, ZnSSe, or a combination thereof. The third zinc chalcogenide may further include or may not include selenium. The outer layer may be an outermost layer of a semiconductor nanoparticle.

In the development of a display device capable of implementing an improved luminance and including a semiconductor nanoparticle as a light-emitter, there is a technical demand for an electroluminescent device that emits blue light in a desired wavelength range. Despite many studies on a semiconductor nanoparticle emitting blue light, it remains challenging to obtain a cadmium free semiconductor nanoparticle emitting blue light of a desired wavelength with improved efficiency and luminance for use in an electroluminescent device. A cadmium free semiconductor nanoparticle emitting green light or red light can obtain a band alignment of a type I structure by arranging a shell on an indium phosphide core, and can implement a desired level of light-emitting properties in an electroluminescent device. However, the present inventors have found that the zinc chalcogenide-based blue light-emitting cadmium free semiconductor nanoparticles may be difficult to exhibit desired electroluminescent properties even by arranging a shell or multilayer shell. Without wishing to be bound by any theory, the blue light-emitting semiconductor nanoparticle may have a type II structure or a pseudo type II structure band alignment, and thus there is a limit in the improvement of efficiency and stability due to relatively low quantum confinement. Increasing the thickness of the shell placed on the core may be one way to deal with this technical issue. However, the present inventors have found that as the thickness of the shell (e.g., the thickness of the shell containing zinc and selenium) increases, the final semiconductor nanoparticle may have an increased number of defects, and the lattice mismatch problem may become more significant, which may lead to an imbalance in the shape of the particle and a deterioration of the properties in the electroluminescent device.

Surprisingly, the present inventors have found that the semiconductor nanoparticle of an embodiment may be synthesized by the method described herein, thereby exhibiting the characteristics described here (i.e., size, composition and thickness in semiconductor nanocrystal shell arrangement, composition as a whole semiconductor nanoparticle, etc.), and can exhibit improved luminous efficiency and improved stability at the desired peak emission wavelength. Without wishing to be bound by a specific theory, it is believed that the number of defects that may occur as the shell thickness increases in the semiconductor nanoparticle of an embodiment may be minimized and the problem of lattice mismatch can be solved.

In the semiconductor nanoparticle of an embodiment, a thickness of the second semiconductor nanocrystal (or the middle shell layer) may be greater than about 2.6 nm, greater than or equal to about 2.7 nm, greater than or equal to about 2.8 nm, greater than or equal to about 2.9 nm, greater than or equal to about 3 nm, greater than or equal to about 3.1 nm, greater than or equal to about 3.2 nm, greater than or equal to about 3.3 nm, greater than or equal to about 3.4 nm, greater than or equal to about 3.5 nm, greater than or equal to about 3.6 nm, greater than or equal to about 3.7 nm, greater than or equal to about 3.8 nm, greater than or equal to about 3.9 nm, greater than or equal to about 4 nm, greater than or equal to about 4.1 nm, greater than or equal to about 4.2 nm, greater than or equal to about 4.3 nm, greater than or equal to about 4.4 nm, greater than or equal to about 4.5 nm, greater than or equal to about 4.6 nm, greater than or equal to about 4.7 nm, greater than or equal to about 4.8 nm, greater than or equal to about 4.9 nm, greater than or equal to about 5 nm, greater than or equal to about 5.1 nm, or greater than or equal to about 5.2 nm. The thickness of the second semiconductor nanocrystal (or the middle shell layer) may be less than or equal to about 6.5 nm, less than or equal to about 6 nm, less than or equal to about 5.9 nm, less than or equal to about 5.8 nm, less than or equal to about 5.7 nm, less than or equal to about 5.6 nm, less than or equal to about 5.5 nm, less than or equal to about 5.4 nm, less than or equal to about 5.3 nm, less than or equal to about 5.2 nm, less than or equal to about 5.1 nm, less than or equal to about 5 nm, less than or equal to about 4.9 nm, less than or equal to about 4.8 nm, less than or equal to about 4.7 nm, less than or equal to about 4.6 nm, less than or equal to about 4.5 nm, less than or equal to about 4.4 nm, less than or equal to about 4.3 nm, or less than or equal to about 4.2 nm.

In the semiconductor nanoparticle of an embodiment, a thickness of the third semiconductor nanocrystal (or the outer layer) may be less than or equal to about 1.2 nm, less than or equal to about 1.1 nm, less than or equal to about 1 nm, less than or equal to about 0.9 nm, or less than or equal to about 0.8 nm. The thickness of the third semiconductor nanocrystal (or the outer layer) may be greater than or equal to about 0.2 nm, greater than or equal to about 0.23 nm, greater than or equal to about 0.25 nm, greater than or equal to about 0.27 nm, greater than or equal to about 0.31 nm, greater than or equal to about 0.33 nm, greater than or equal to about 0.35 nm, greater than or equal to about 0.37 nm, greater than or equal to about 0.39 nm, greater than or equal to about 0.41 nm, greater than or equal to about 0.43 nm, greater than or equal to about 0.45 nm, greater than or equal to about 0.47 nm, greater than or equal to about 0.49 nm, or greater than or equal to about 0.5 nm.

Surprisingly, the present inventors have found that the shell layer thickness of the second semiconductor nanocrystal (e.g., ZnSe) and the shell layer thickness of the third semiconductor nanocrystal (e.g., ZnS shell layer thickness) can be adjusted to the range described herein to control strain and mismatch that can occur in the lattice.

In the semiconductor nanoparticle of an embodiment, a thickness of the semiconductor nanocrystal shell may be greater than about 3.8 nm, greater than or equal to about 3.9 nm, greater than or equal to about 4 nm, greater than or equal to about 4.2 nm, greater than or equal to about 4.5 nm, greater than or equal to about 4.8 nm, greater than or equal to about 5 nm, greater than or equal to about 5.2 nm, greater than or equal to about 5.4 nm, or greater than or equal to about 5.5 nm. The thickness of the semiconductor nanocrystal shell may be less than or equal to about 20 nm, less than or equal to about 15 nm, less than or equal to about 10 nm, less than or equal to about 8 nm, less than or equal to about 7 nm, less than or equal to about 6 nm, or less than or equal to about 5.7 nm.

In the semiconductor nanoparticle of an embodiment, a mole ratio of selenium to a sum of selenium and sulfur [Se:(Se+S)] may be greater than or equal to about 0.55:1, greater than or equal to about 0.555:1, greater than or equal to about 0.56:1, greater than or equal to about 0.561:1, greater than or equal to about 0.563:1, greater than or equal to about 0.565:1, greater than or equal to about 0.567:1, greater than or equal to about 0.569:1, greater than or equal to about 0.57:1, greater than or equal to about 0.571:1, greater than or equal to about 0.573:1, greater than or equal to about 0.575:1, greater than or equal to about 0.577:1, greater than or equal to about 0.579:1, greater than or equal to about 0.58:1, greater than or equal to about 0.581:1, greater than or equal to about 0.583:1, greater than or equal to about 0.585:1, greater than or equal to about 0.587:1, greater than or equal to about 0.589:1, greater than or equal to about 0.59:1, greater than or equal to about 0.591:1, greater than or equal to about 0.593:1, greater than or equal to about 0.595:1, greater than or equal to about 0.597:1, or greater than or equal to about 0.6:1. The mole ratio of selenium to a sum of selenium and sulfur [Se:(Se+S)] may be less than or equal to about 0.99:1, less than or equal to about 0.97:1, less than or equal to about 0.95:1, less than or equal to about 0.94:1, less than or equal to about 0.92:1, less than or equal to about 0.88:1, less than or equal to about 0.86:1, less than or equal to about 0.84:1, less than or equal to about 0.82:1, less than or equal to about 0.78:1, less than or equal to about 0.76:1, less than or equal to about 0.74:1, less than or equal to about 0.72:1, less than or equal to about 0.7:1, less than or equal to about 0.68:1, less than or equal to about 0.66:1, less than or equal to about 0.64:1, less than or equal to about 0.62:1, less than or equal to about 0.61:1, less than or equal to about 0.6:1, less than or equal to about 0.58:1, or less than or equal to about 0.56:1.

The semiconductor nanoparticle may further include tellurium.

In the semiconductor nanoparticle of an embodiment, a mole ratio of tellurium to sulfur (Te:S) may be greater than or equal to about 0.005:1, greater than or equal to about 0.007:1, greater than or equal to about 0.008:1, greater than or equal to about 0.009:1, or greater than or equal to about 0.01:1. The mole ratio of tellurium to sulfur (Te:S) may be less than or equal to about 0.1:1, less than or equal to about 0.09:1, less than or equal to about 0.08:1, less than or equal to about 0.07:1, less than or equal to about 0.06:1, less than or equal to about 0.05:1, less than or equal to about 0.04:1, less than or equal to about 0.03:1, less than or equal to about 0.02:1, or less than or equal to about 0.015:1.

In the semiconductor nanoparticle of an embodiment, a mole ratio of tellurium to selenium (Te:Se) may be less than or equal to about 0.1:1, less than or equal to about 0.08:1, less than or equal to about 0.07:1, less than or equal to about 0.06:1, less than or equal to about 0.05:1, less than or equal to about 0.045:1, less than or equal to about 0.04:1, less than or equal to about 0.035:1, less than or equal to about 0.03:1, less than or equal to about 0.025:1, less than or equal to about 0.02:1, less than or equal to about 0.015:1, less than or equal to about 0.01:1, less than or equal to about 0.009:1, less than or equal to about 0.008:1, less than or equal to about 0.007:1, less than or equal to about 0.006:1, or less than or equal to about 0.005:1. The mole ratio of tellurium to selenium (Te:Se) may be greater than or equal to about 0.0001:1, greater than or equal to about 0.00015:1, greater than or equal to about 0.0002:1, greater than or equal to about 0.00025:1, greater than or equal to about 0.0003:1, greater than or equal to about 0.00035:1, greater than or equal to about 0.0004:1, greater than or equal to about 0.00045:1, greater than or equal to about 0.0005:1, greater than or equal to about 0.00055:1, greater than or equal to about 0.006:1, greater than or equal to about 0.00065:1, greater than or equal to about 0.0007:1, greater than or equal to about 0.00075:1, greater than or equal to about 0.0008:1, greater than or equal to about 0.00085:1, greater than or equal to about 0.0009:1, greater than or equal to about 0.00095:1, greater than or equal to about 0.001:1, greater than or equal to about 0.0015:1, greater than or equal to about 0.002:1, greater than or equal to about 0.0025:1, greater than or equal to about 0.003:1, greater than or equal to about 0.0035:1, greater than or equal to about 0.004:1, or greater than or equal to about 0.0045:1. In the semiconductor nanoparticle of an embodiment, the mole ratio of tellurium to selenium (Te:Se) may be from about 0.004:1 to about 0.01:1. The mole ratio of tellurium to selenium (Te:Se) may be from about 0.0002:1 to about 0.02:1. The mole ratio of tellurium to selenium (Te:Se) may be from about 0.0003:1 to about 0.03:1.

In the semiconductor nanoparticle of an embodiment, a mole ratio of tellurium to zinc (Te:Zn) may be less than or equal to about 0.02:1, less than or equal to about 0.019:1, less than or equal to about 0.018:1, less than or equal to about 0.017:1, less than or equal to about 0.016:1, less than or equal to about 0.015:1, less than or equal to about 0.014:1, less than or equal to about 0.013:1, less than or equal to about 0.012:1, less than or equal to about 0.011:1, less than or equal to about 0.01:1, less than or equal to about 0.009:1, less than or equal to about 0.008:1, less than or equal to about 0.007:1, less than or equal to about 0.006:1, or less than or equal to about 0.005:1. The mole ratio of tellurium to zinc (Te:Zn) may be greater than or equal to about 0.0001:1, greater than or equal to about 0.0002:1, greater than or equal to about 0.0003:1, greater than or equal to about 0.0004:1, greater than or equal to about 0.0005:1, greater than or equal to about 0.0006:1, greater than or equal to about 0.0007:1, greater than or equal to about 0.0008:1, greater than or equal to about 0.0009:1, greater than or equal to about 0.001:1, greater than or equal to about 0.0011:1, greater than or equal to about 0.0012:1, greater than or equal to about 0.0013:1, greater than or equal to about 0.0014:1, greater than or equal to about 0.0015:1, greater than or equal to about 0.0016:1, greater than or equal to about 0.0017:1, greater than or equal to about 0.0018:1, greater than or equal to about 0.0019:1, greater than or equal to about 0.002:1, greater than or equal to about 0.0021:1, greater than or equal to about 0.0022:1, greater than or equal to about 0.0023:1, greater than or equal to about 0.0024:1, greater than or equal to about 0.0025:1, greater than or equal to about 0.0026:1, greater than or equal to about 0.0027:1, greater than or equal to about 0.0028:1, greater than or equal to about 0.0029:1, greater than or equal to about 0.003:1, greater than or equal to about 0.0031:1, greater than or equal to about 0.0032:1, greater than or equal to about 0.0033:1, greater than or equal to about 0.0034:1, greater than or equal to about 0.0035:1, greater than or equal to about 0.0036:1, greater than or equal to about 0.0037:1, greater than or equal to about 0.0038:1, greater than or equal to about 0.0039:1, or greater than or equal to about 0.004:1.

In the semiconductor nanoparticle of an embodiment, a mole ratio of selenium to zinc (Se:Zn) may be less than about 1:1, for example, less than or equal to about 0.95:1, less than or equal to about 0.90:1, less than or equal to about 0.85:1, less than or equal to about 0.8:1, less than or equal to about 0.7:1, less than or equal to about 0.6:1, less than or equal to about 0.55:1, less than or equal to about 0.5:1, less than or equal to about 0.45:1, or less than or equal to about 0.4:1. The mole ratio of selenium to zinc (Se:Zn) may be greater than or equal to about 0.1:1, greater than or equal to about 0.2:1, greater than or equal to about 0.3:1, greater than or equal to about 0.4:1, greater than or equal to about 0.45:1, greater than or equal to about 0.46:1, greater than or equal to about 0.48:1, greater than or equal to about 0.5:1, greater than or equal to about 0.52:1, greater than or equal to about 0.53:1, greater than or equal to about 0.54:1, greater than or equal to about 0.55:1, greater than or equal to about 0.56:1, greater than or equal to about 0.57:1, greater than or equal to about 0.58:1, greater than or equal to about 0.59:1, or greater than or equal to about 0.6:1.

In the semiconductor nanoparticle of an embodiment, a mole ratio of a sum of selenium and sulfur to zinc [(S+Se):Zn] may be greater than or equal to about 0.5:1, greater than or equal to about 0.6:1, greater than or equal to about 0.7:1, greater than or equal to about 0.8:1, greater than or equal to about 0.85:1, greater than or equal to about 0.88:1, greater than or equal to about 0.89:1, greater than or equal to about 0.9:1, greater than or equal to about 0.91:1, greater than or equal to about 0.92:1, greater than or equal to about 0.93:1, greater than or equal to about 0.94:1, greater than or equal to about 0.95:1, greater than or equal to about 0.96:1, greater than or equal to about 0.97:1, greater than or equal to about 0.98:1, greater than or equal to about 0.99:1, or greater than or equal to about 1:1. In the semiconductor nanoparticle of an embodiment, a mole ratio of a sum of selenium and sulfur to zinc [(S+Se):Zn] may be less than or equal to about 3:1, less than or equal to about 2.5:1, less than or equal to about 2:1, less than or equal to about 1.5:1, or less than or equal to about 1.2:1.

In the semiconductor nanoparticle of an embodiment, a mole ratio of sulfur to selenium (S:Se) may be less than or equal to about 0.8:1, less than or equal to about 0.77:1, less than or equal to about 0.75:1, less than or equal to about 0.73:1, less than or equal to about 0.7:1, less than or equal to about 0.696:1, less than or equal to about 0.69:1, less than or equal to about 0.686:1, less than or equal to about 0.683:1, less than or equal to about 0.68:1, or less than or equal to about 0.67. In the semiconductor nanoparticle of an embodiment, a mole ratio of sulfur to selenium (S:Se) may be greater than or equal to about 0.3:1, greater than or equal to about 0.35:1, greater than or equal to about 0.4:1, greater than or equal to about 0.45:1, greater than or equal to about 0.5:1, greater than or equal to about 0.55:1, greater than or equal to about 0.6:1, greater than or equal to about 0.62:1, greater than or equal to about 0.64:1, greater than or equal to about 0.65:1, greater than or equal to about 0.67:1, greater than or equal to about 0.682:1, greater than or equal to about 0.685:1, greater than or equal to about 0.7:1, greater than or equal to about 0.74:1, or greater than or equal to about 0.76:1.

A mole amount of an element or a mole ratio among elements (for example, included in the semiconductor nanoparticle or the light emitting layer) as described herein may be determined through, e.g., with, an appropriate analysis tool (e.g., an inductively coupled plasma atomic emission spectroscopy (ICP-AES), an X-ray photoelectron spectroscopy (XPS), an ion chromatography, a transmission electron microscopy energy-dispersive X-ray spectroscopy (TEM-EDX), a scanning electron microscopy energy-dispersive X-ray spectroscopy (SEM-EDX), a X-ray fluorescence (XRF), or a combination thereof).

The semiconductor nanoparticles disclosed herein may exhibit a relatively increased particle size (or average particle size). The particle size of the semiconductor nanoparticles may be a diameter or an equivalent diameter calculated under an assumption of a sphere. The particle size of the semiconductor nanoparticle can be determined from an electron microscope image (for example, a transmission electron microscopy image). The particle size (or the average particle size) of the semiconductor nanoparticle may be greater than or equal to about 11.5 nm, greater than or equal to about 11.8 nm, greater than or equal to about 11.9 nm, greater than or equal to about 12 nm, greater than or equal to about 12.3 nm, greater than or equal to about 12.4 nm, greater than or equal to about 12.5 nm, greater than or equal to about 12.8 nm, greater than or equal to about 13 nm, greater than or equal to about 13.5 nm, greater than or equal to about 14 nm, or greater than or equal to about 14.2 nm. The particle size (or the average particle size) of the semiconductor nanoparticle may be less than or equal to about 50 nm, less than or equal to about 40 nm, less than or equal to about 35 nm, less than or equal to about 29 nm, less than or equal to about 28 nm, less than or equal to about 27 nm, less than or equal to about 26 nm, less than or equal to about 25 nm, less than or equal to about 24 nm, less than or equal to about 23 nm, less than or equal to about 22 nm, less than or equal to about 21 nm, less than or equal to about 20 nm, less than or equal to about 19 nm, less than or equal to about 18 nm, less than or equal to about 17.5 nm, less than or equal to about 17 nm, less than or equal to about 16.5 nm, less than or equal to about 16 nm, less than or equal to about 15.5 nm, less than or equal to about 15 nm, or less than or equal to about 14.5 nm. As used herein, the average may be a mean average. As used herein, the average may be median.

In the semiconductor nanoparticles of an embodiment, a standard deviation of the particle size may be in a range of from about 1% to about 20%, about 2% to about 19%, about 3% to about 18%, from about 4% to about 17%, from about 5% to about 16%, from about 6% to about 14%, from about 7% to about 13%, from about 8% to about 12%, from about 9% to about 11%, or a combination thereof. The semiconductor nanoparticles of one embodiment may have a standard deviation of 10% or less, 9% or less, 8% or less, 7% or less, 6% or less, or 5% or less of the average size.

In an embodiment, the particle size may be readily and reproducibility analyzed and obtained by using an image (a two-dimensional image) obtained from an electron microscopic analysis (e.g., a transmission electron microscopy analysis or a scanning electron microscopy) and using any appropriate (known or commercially available) image analysis program such as “image J,” for example, according to a manual provided with a manufacturer. The image analysis tool and measurement conditions are not particularly limited.

In an embodiment, the nanoparticles (e.g., the core or the shell) may include or may not include an indium phosphide, a gallium phosphide, an indium gallium phosphide (e.g., a Group III-V compound including indium, gallium, or a combination thereof); or may or may not include manganese, copper, or a combination thereof.

The semiconductor nanoparticles according to an embodiment may have a relatively thick middle shell layer (e.g., containing a ZnSe) and an increased particle size, and the formation or the size growth of such a shell layer can be uniformly controlled by the methods described herein (e.g., including a reaction conducted at a relatively high temperature, the adoption of an additive, or a combination thereof, a reduction of an unreacted precursors, etc.). Without wishing to be bound by a particular theory, it is believed that by employing the method of an embodiment, the formation of the shell layer can achieve particle growth through substantially the same crystal plane and the occurrence of defects may be suppressed.

The aspect ratio may be determined for a fitted ellipse obtained from the two-dimensional image of the semiconductor nanoparticle in an electron microscope analysis (e.g., a transmission electron microscopy analysis), and in the determination of the aspect ratio, a dimension of a major axis is divided by a dimension of the minor axis.

In an embodiment, a fitted ellipse may be chosen during the analysis of the images of particles obtained from the electron microscopy using a general or commercial image analysis tool (e.g., Image J) and a major axis and a minor axis for the fitted ellipse can be determined.

In an embodiment, the semiconductor nanoparticle may exhibit an (average) aspect ratio (major axis:minor axis) of, for example, less than or equal to about 1.19:1, less than or equal to about 1.18:1, less than or equal to about 1.17:1, less than or equal to about 1.16:1, less than or equal to about 1.15:1, less than or equal to about 1.14:1, less than or equal to about 1.13:1, less than or equal to about 1.12:1, less than or equal to about 1.11:1, or less than or equal to about 1.1:1, as determined from a two-dimensional image obtained from an electron microscopy analysis such as transmission electron microscopy (“TEM”) analysis. In an embodiment, the semiconductor nanoparticle may exhibit an (average) aspect ratio of greater than or equal to about 1:1, greater than or equal to about 1.02:1, greater than or equal to about 1.04:1, greater than or equal to about 1.06:1, greater than or equal to about 1.08:1, or greater than or equal to about 1.09:1, as determined from a two-dimensional image obtained from an electron microscopy analysis such as TEM analysis.

The semiconductor nanoparticle according to an embodiment may have a relatively reduced level of circularity. The circularity may be determined by the following definition in a two-dimensional image obtained by an electron microscopy analysis:

$$circularity = 4 π \times \frac{Area}{{[ Perimeter ]}^{2}}$$

wherein “Area” is an area of a two-dimensional image(s) of individual semiconductor nanoparticle(s), and “Perimeter” is a circumference of a two-dimensional image(s) of individual semiconductor nanoparticle(s).

In an embodiment, the semiconductor nanoparticle may have a circularity or an average circularity (referred to as “circularity” herein) of less than or equal to about 0.8, less than or equal to about 0.79, less than or equal to about 0.78, less than or equal to about 0.77, less than or equal to about 0.76, less than or equal to about 0.75, less than or equal to about 0.74, or less than or equal to about 0.73. The circularity may be greater than or equal to about 0.65, greater than or equal to about 0.7, greater than or equal to about 0.72, greater than or equal to about 0.73, greater than or equal to about 0.74, greater than or equal to about 0.75, or greater than or equal to about 0.76. In an embodiment, the semiconductor nanoparticle may have a standard deviation of the circularity that is greater than or equal to about 0%, greater than or equal to about 0.1%, greater than or equal to about 0.5%, or greater than or equal to about 0.7% of its average value. The standard deviation of the circularity may be less than or equal to about 7%, less than or equal to about 6%, less than or equal to about 5%, less than or equal to about 4%, less than or equal to about 3%, or less than or equal to about 2.5% of its average value.

The solidity, S is defined by the following equation, as the image area A, divided by the convex hull area, Ac.

$$S = \frac{A}{{A}_{c}}$$

A: an area of a two-dimensional image of an individual semiconductor nanoparticle
Ac: an area of a convex hull the two-dimensional image of an individual semiconductor nanoparticle

In an embodiment, the semiconductor nanoparticle or a population thereof may have a solidity or an average solidity (referred to as “solidity” herein) of greater than or equal to about 0.9, greater than or equal to about 0.91, greater than or equal to about 0.92, greater than or equal to about 0.93, greater than or equal to about 0.94, or greater than or equal to about 0.95 and less than or equal to about 1, less than or equal to about 0.99, less than or equal to about 0.98, less than or equal to about 0.97, less than or equal to about 0.96, or less than or equal to about 0.95.

The shape factors (e.g., the circularity, or the solidity) may be obtained readily and reproducibility from a two-dimensional electron microcopy image of the particles using a universal image analysis program (e.g., Image J developed by NIH) and a manual of the program producer (e.g., Image J User Guide IJ 1.46r) or an in-house image program made by a coding language (e.g., a commercially available coding language such as Matlab).

In an embodiment, the semiconductor nanoparticle or the electroluminescent device may be configured to emit blue light. In an embodiment, the semiconductor nanoparticle or the electroluminescent device may emit blue light, for example, by the irradiation of light excitation, e.g., when irradiated with light, or by an applied voltage. A peak emission wavelength of the blue light may be greater than or equal to about 430 nm, greater than or equal to about 435 nm, greater than or equal to about 440 nm, greater than or equal to about 446 nm, greater than or equal to about 449 nm, greater than or equal to about 450 nm, greater than or equal to about 455 nm, greater than or equal to about 460 nm, greater than or equal to about 465 nm, greater than or equal to about 470 nm, or greater than or equal to about 477 nm and less than or equal to about 480 nm, less than or equal to about 470 nm, less than or equal to about 465 nm, less than or equal to about 460 nm, or less than or equal to about 455 nm.

A peak emission wavelength or a photoluminescent (or electroluminescent) wavelength of the blue light or the semiconductor nanoparticle may be greater than or equal to about 455 nm, greater than or equal to about 456 nm, greater than or equal to about 457 nm, greater than or equal to about 458 nm, greater than or equal to about 459 nm, greater than or equal to about 460 nm, greater than or equal to about 461 nm, greater than or equal to about 462 nm, greater than or equal to about 463 nm, greater than or equal to about 464 nm, greater than or equal to about 465 nm, greater than or equal to about 466 nm, greater than or equal to about 467 nm, greater than or equal to about 468 nm, greater than or equal to about 469 nm, or greater than or equal to about 470 nm. The photoluminescent wavelength is a peak emission wavelength of the light which the semiconductor nanoparticle or the light emitting layer including the same emits by the irradiation of an incident light, e.g., when irradiated with incident light.

A peak emission wavelength or a photoluminescent (or electroluminescent) wavelength of the blue light or the semiconductor nanoparticle may be less than or equal to about 480 nm, less than or equal to about 479 nm, less than or equal to about 478 nm, less than or equal to about 477 nm, less than or equal to about 476 nm, less than or equal to about 475 nm, less than or equal to about 474 nm, less than or equal to about 473 nm, less than or equal to about 471 nm, or less than or equal to about 470 nm.

The semiconductor nanoparticle of an embodiment may exhibit increased light emitting efficiency together with the peak emission wavelength or the photoluminescent wavelength described herein. The semiconductor nanoparticle may emit light, for example, in a solution state or as a light emitting film as being, e.g., when, irradiated with an incident light and exhibit a quantum yield (for example, an absolute quantum yield) that is greater than about 75%, for example, greater than or equal to about 76%, greater than or equal to about 77%, greater than or equal to about 78%, greater than or equal to about 79%, greater than or equal to about 80%, greater than or equal to about 81%, greater than or equal to about 82%, greater than or equal to about 83%, greater than or equal to about 84%, greater than or equal to about 85%, greater than or equal to about 86%, greater than or equal to about 87%, greater than or equal to about 88%, or greater than or equal to about 89%. The quantum yield of the semiconductor nanoparticle may be from about 76% to about 100%, from about 80% to about 99%, from about 84% to about 97%, from about 86% to about 96%, from about 87% to about 95%, from about 88% to about 94%, from about 89% to about 93%, from about 90% to about 92%, or a combination thereof. The quantum yield may be an absolute quantum yield or a relative quantum yield.

The semiconductor nanoparticles of an embodiment may exhibit a (maximum) luminescent peak having a desired full width at half maximum as a voltage is applied or as an incident light is irradiated, e.g., when irradiated with incident light. The full width at half maximum may be from about 5 nm to about 55 nm, from about 8 nm to about 54 nm, from about 9 nm to about 53 nm, from about 10 nm to about 52 nm, from about 11 nm to about 51 nm, from about 12 nm to about 50 nm, from about 13 nm to about 49 nm, from about 14 nm to about 48 nm, from about 15 nm to about 47 nm, from about 16 nm to about 46 nm, from about 17 nm to about 45 nm, from about 18 nm to about 44 nm, from about 19 nm to about 43 nm, from about 20 nm to about 42 nm, from about 21 nm to about 41 nm, from about 22 nm to about 40 nm, from about 25 nm to about 35 nm, from about 28 nm to about 32 nm, or a combination thereof.

In an embodiment, the semiconductor nanoparticles may further include fluorine, chlorine, or a combination thereof. In an embodiment, the semiconductor nanoparticle may not include fluorine, chlorine, or a combination thereof. In an embodiment, the semiconductor nanoparticle may further include an additional metal. The additional metal may include aluminum, alkali metal (e.g., sodium, potassium, etc.), or a combination thereof. The additional metal may be derived from an additive used in the method described herein. The amount of the additional metal in the semiconductor nanoparticle of an embodiment may be, per 100 moles of selenium, greater than or equal to about 0.01 moles, greater than or equal to about 0.1 moles, greater than or equal to about 0.2 moles, greater than or equal to about 0.5 moles, greater than or equal to about 1 mole, greater than or equal to about 2 moles, greater than or equal to about 5 moles, or greater than or equal to about 10 moles. The amount of the additional metal in the semiconductor nanoparticle of an embodiment may be, per 100 moles of selenium, less than or equal to about 50 moles, less than or equal to about 40 moles, less than or equal to about 30 moles, less than or equal to about 20 moles, less than or equal to about 10 moles, less than or equal to about 5 moles, less than or equal to about 1 mole, or less than or equal to about 0.5 moles.

In an embodiment, the semiconductor nanoparticles may be prepared according to the method described herein. In an embodiment, the method of preparing the semiconductor nanoparticles includes preparing a semiconductor nanocrystal shell by contacting, e.g., reacting, a zinc precursor with a chalcogen precursor in the presence of the first semiconductor nanocrystal including the first zinc chalcogenide. The chalcogen precursor includes a selenium precursor and a sulfur precursor.

In the method of an embodiment, the reaction of the zinc precursor and the chalcogen precursor is carried out in the presence of an additive, and the additive includes an alkali metal compound and a metal halide (e.g., a metal chloride). The metal halide (e.g., the metal chloride) may include a zinc chloride, an aluminum chloride, or a combination thereof.

In the method of an embodiment, a reaction of a zinc precursor and a selenium precursor may be carried out in the presence of the additive (e.g., an alkali metal compound). In the method of an embodiment, the reaction between a zinc precursor and a sulfur precursor may be carried out in the presence of the additive (e.g., an alkali metal compound, a metal halide, or a combination thereof). In the method of an embodiment, the additive may be added to a reaction system at the same time as or after the addition of the selenium precursor. In the method of an embodiment, the additive may be added to a reaction system at the same time or after the addition of the sulfur precursor.

In the method of an embodiment, the reaction temperature may be greater than or equal to about 335° C., greater than or equal to about 340° C., or greater than 340° C.

In an embodiment, the preparation of the first semiconductor nanocrystal or the core including the same is not particularly limited and may be selected appropriately. In an embodiment, the first semiconductor nanocrystal or the core may be obtained by preparing a zinc precursor solution including a zinc precursor and an organic ligand; preparing a selenium precursor and a tellurium precursor; and heating the zinc precursor solution up to a core formation temperature and adding the selenium precursor and the tellurium precursor optionally together with an organic ligand and performing a core formation reaction.

In the core formation reaction, a ratio (e.g., a mole ratio of the tellurium precursor to the selenium precursor) or a reaction time can be selected appropriately taking into consideration a peak emission wavelength of the final semiconductor nanoparticle, a reactivity of the precursor, and a reaction temperature. The core formation reaction temperature can be appropriately selected, as well. The core formation reaction temperature may be greater than or equal to 280° C., for example, greater than or equal to 290° C. The reaction temperature for core formation may be in the range of from about 280° C. to about 340° C., for example, about 290° C. to about 330° C., or about 300° C. to about 320° C. The reaction time for the core formation can be adjusted taking into consideration a desired core size and reactivity of the precursor and is not particularly limited. The reaction time may be greater than or equal to 5 minutes, greater than or equal to 30 minutes, or greater than or equal to 50 minutes, but is not limited thereto. For example, the reaction time may be 2 hours or less but is not limited thereto. The formed core may not be separated or may be separated from a reaction system (e.g., via non-solvent precipitation). In an embodiment, the separated core may be washed and added to a subsequent reaction.

In an embodiment, a zinc precursor, a solvent (e.g., organic solvent), and optionally an organic ligand may be heated (or vacuum-treated) at a predetermined temperature (e.g., greater than or equal to about 100° C. and less than or equal to about 180° C.) under vacuum, and the reaction system may be heated to a reaction temperature after the change of the atmosphere inside the reaction vessel into an inert gas atmosphere. The first semiconductor nanocrystal and the chalcogen precursor may be added to the reaction system to proceed with the reaction. Reaction conditions such as reaction temperature and time for a shell formation may be appropriately selected in consideration of a desired shell composition.

The chalcogen precursors may be added to a reaction system simultaneously or sequentially, taking into consideration the final composition, to form a shell having a desired composition (e.g., having a gradient or multi-layered shell). In an embodiment, a zinc precursor and a selenium precursor may be reacted to form a first shell layer (e.g., an intermediate or middle shell layer), and then a zinc precursor and a sulfur precursor may be reacted to form a second shell layer (e.g., an outer shell layer).

The chalcogen precursor may include a selenium precursor, a sulfur precursor, or a combination thereof. In an embodiment, reacting the zinc precursor and the chalcogen precursors include reacting the zinc precursor with the selenium precursor to form a second semiconductor nanocrystal (or an intermediate or middle shell layer including the same), and reacting the zinc precursor and the sulfur precursor (e.g., on the intermediate or middle shell layer) to form a third semiconductor nanocrystal (or an outer shell layer including the same).

Regarding the formation of the middle shell layer, an amount of selenium precursor used per mole of the zinc precursor may be greater than or equal to about 0.1 moles, greater than or equal to about 0.3 moles, greater than or equal to about 0.5 moles, greater than or equal to about 0.65 moles, greater than or equal to about 0.7 moles, greater than or equal to about 0.9 moles, greater than or equal to about 1 mole, greater than or equal to about 1.5 moles, or greater than or equal to about 2 moles. Regarding the formation of the middle shell layer, an amount of selenium precursor used per mole of zinc precursor may be less than or equal to about 5 moles, less than or equal to about 4 moles, less than or equal to about 3 moles, less than or equal to about 2 moles, or less than or equal to about 1 mole. Regarding the formation of the outer shell layer, an amount of the sulfur precursor used per mole of zinc precursor may be greater than or equal to about 0.1 moles, greater than or equal to about 0.3 moles, greater than or equal to about 0.5 moles, greater than or equal to about 0.7 moles, greater than or equal to about 0.9 moles, greater than or equal to about 1 mole, greater than or equal to about 1.3 moles, greater than or equal to about 1.5 moles, or greater than or equal to about 2 moles. Regarding the formation of the outer shell layer, an amount of the sulfur precursor used per mole of zinc precursor may be less than or equal to about 5 moles, less than or equal to about 4 moles, less than or equal to about 3 moles, less than or equal to about 2 moles, or less than or equal to about 1 mole.

An amount of the zinc precursor used for forming the intermediate or the middle shell layer and an amount of the zinc precursor used for forming the outer shell layer may be appropriately selected so that the semiconductor nanoparticle may have a thickness of each of the shell layers, a thickness ratio therebetween, or a combination thereof as set forth herein.

In the method of an embodiment, the amount of the sulfur precursor used for, e.g., per, 1 mole of the selenium precursor may be greater than or equal to about 0.1 moles, greater than or equal to about 0.5 moles, greater than or equal to about 0.65 moles, greater than or equal to about 0.7 moles, greater than or equal to about 0.9 moles, greater than or equal to about 1 moles, greater than or equal to about 1.1 moles, greater than or equal to about 1.3 moles, greater than or equal to about 1.5 moles, greater than or equal to about 1.7 moles, or greater than or equal to about 2 moles. In the method of an embodiment, the amount of the sulfur precursor used for, e.g., per, 1 mole of the selenium precursor may be less than or equal to about 3 moles, less than or equal to about 2.5 moles, less than or equal to about 2 moles, less than or equal to about 1.8 moles, less than or equal to about 1.6 moles, less than or equal to about 1.4 moles, less than or equal to about 1.2 moles, less than or equal to about 0.8 moles, or less than or equal to about 0.6 moles.

In the method of an embodiment, the amount of the alkali metal compound used per mole of the chalcogen precursor (for example, per 1 mole of the selenium precursor) may be greater than or equal to about 0.0001 moles, greater than or equal to about 0.001 moles, greater than or equal to about 0.005 moles, greater than or equal to about 0.01 moles, greater than or equal to about 0.05 moles, greater than or equal to about 0.1 moles, greater than or equal to about 0.2 moles, greater than or equal to about 0.3 moles, greater than or equal to about 0.4 moles, or greater than or equal to about 0.5 moles. In the method of an embodiment, the amount of the alkali metal compound used per mole of the chalcogen precursor (for example, per 1 mole of the selenium precursor) may be less than or equal to about 1 mole, less than or equal to about 0.5 moles, less than or equal to about 0.3 moles, less than or equal to about 0.1 moles, less than or equal to about 0.08 moles, less than or equal to about 0.06 moles, or less than or equal to about 0.01 moles.

In the method of an embodiment, the amount of a zinc chloride used per mole of the chalcogen precursor (e.g., per 1 mole of the sulfur precursor) may be greater than or equal to about 0.0001 moles, greater than or equal to about 0.001 moles, greater than or equal to about 0.005 moles, greater than or equal to about 0.01 moles, greater than or equal to about 0.05 moles, greater than or equal to about 0.1 moles, greater than or equal to about 0.2 moles, greater than or equal to about 0.3 moles, greater than or equal to about 0.4 moles, or greater than or equal to about 0.5 moles. In the method of an embodiment, the amount of a zinc chloride used per mole of the chalcogen precursor (e.g., per 1 mole of the sulfur precursor) may be less than or equal to about 1 mole, less than or equal to about 0.5 moles, less than or equal to about 0.3 moles, less than or equal to about 0.1 moles, less than or equal to about 0.08 moles, less than or equal to about 0.06 moles, or less than or equal to about 0.01 moles.

In the method of an embodiment, the amount of aluminum chloride used per mole of the chalcogen precursor (e.g., per 1 mole of the sulfur precursor) may be greater than or equal to about 0.0001 moles, greater than or equal to about 0.001 moles, greater than or equal to about 0.005 moles, greater than or equal to about 0.01 moles, greater than or equal to about 0.05 moles, greater than or equal to about 0.1 moles, greater than or equal to about 0.2 moles, greater than or equal to about 0.3 moles, greater than or equal to about 0.4 moles, or greater than or equal to about 0.5 moles. In the method of an embodiment, the amount of aluminum chloride used per mole of the chalcogen precursor (e.g., per 1 mole of the sulfur precursor) may be less than or equal to about 1 mole, less than or equal to about 0.5 moles, less than or equal to about 0.3 moles, less than or equal to about 0.1 moles, less than or equal to about 0.08 moles, less than or equal to about 0.06 moles, or less than or equal to about 0.01 moles.

In the method of an embodiment, when two or more types of metal chloride are used, the ratio between each of the metal chlorides may be from about 1:0.1 to about 1:10, from about 1:0.3 to about 1:3, from about 1:0.5 to about 1:2, from about 1:1 to about 1:1.2, or a combination thereof.

The addition of a chalcogen precursor (e.g., a selenium precursor or a sulfur precursor) may be conducted in a split (injection) manner. In the method of an embodiment, the selenium precursor may be added or injected into the reaction system two or more times (three or more times, four or more times, five or more times, six or more times, seven or more times, eight or more times, or nine or more times) intermittently and in the same or different amounts, respectively. In the method of an embodiment, the sulfur precursor may be added or injected into the reaction system optionally together with the zinc precursor simultaneously or in a split manner (e.g., two or more times (e.g., three or more times, four or more times, five or more times)). The selenium precursor and the sulfur precursor may be added or injected separately or simultaneously (e.g., as a mixture). In the method of an embodiment, an addition (or an injection) of the sulfur precursor may be started after the injection of a predetermined amount of the selenium precursor is completed.

The method further includes adding an additive (i.e., an alkali metal compound; and a metal chloride) to the reaction system either after addition of the chalcogen precursor or together with the chalcogen precursor. The reaction between the zinc precursor and the selenium precursor may be carried out in the presence of the additive (e.g., the alkali metal compound, the metal chloride, or a combination thereof). The reaction between the zinc precursor and the sulfur precursor may be carried out in the presence of the additive (e.g., the alkali metal compound, the metal chloride, or a combination thereof). The metal chloride may include a zinc chloride, an aluminum chloride, or a combination thereof. In the method of an embodiment, the additive may be added to the reaction system once or at least twice during the formation of the second semiconductor nanocrystal (or the intermediate or middle shell layer), and/or the formation of the third semiconductor nanocrystal as disclosed herein (or the outer shell layer). In the method of an embodiment, the additive may be added after a chalcogen precursor (e.g., a selenium precursor) is added to the reaction system. In the method of an embodiment, the additive may be added after a chalcogen precursor (e.g., a sulfur precursor) is added to the reaction system.

In an embodiment, the additive (e.g., an alkali metal compound) may be added to the reaction system before injection of the selenium precursor, after injection of the selenium precursor, or simultaneously with the injection of the selenium precursor. In an embodiment, the additive may be added at least two of the aforementioned time points. In an embodiment, the additive (e.g., an alkali metal compound and a metal chloride) may be added before, after, or simultaneously with the sulfur precursor. In the method of an embodiment, the selenium precursor may be added before the sulfur precursor. In the method of an embodiment, the order of injection of the chalcogen precursors may be adjusted taking into consideration the composition/structure of the second semiconductor nanocrystal of the final semiconductor nanoparticles.

The alkali metal compound may include sodium, potassium, or a combination thereof. The alkali metal compound may be an alkali metal fatty acid salt (e.g., having a C5 to C50 alkyl group, C8 to C40 alkyl group, C12 to C30 alkyl group, C14 to C25 alkyl group, or a combination thereof), such as sodium oleate, potassium oleate, or the like.

The present inventors have found that during the reaction between the zinc precursor and the chalcogen precursor in the presence of the first semiconductor nanocrystal, a shape distortion of a resulting semiconductor nanocrystal may become significant as the reaction time is elapsed (i.e., as the size of the nanoparticle increases). Without wishing to be bound by a specific theory, it is believed that depending on the positions of the particle or the lattice mismatch in the crystal plane, a difference between growth rates may occur during the reaction.

The reaction temperature for shell formation may be greater than or equal to about 340° C., greater than or equal to about 342° C., greater than or equal to about 345° C., greater than or equal to about 350° C., greater than or equal to about 355° C., or greater than or equal to about or 360° C. The reaction temperature for shell formation may be less than or equal to about 380° C., less than or equal to about 370° C., less than or equal to about 360° C., less than or equal to about 355° C., or less than or equal to about 350° C.

Surprisingly, the present inventors have found that in the method of an embodiment, as the particle size is increased (e.g., even when an increased content of semiconductor nanocrystal shell is arranged) while controlling the reaction temperature within the described range, uniform growth of particles can be achieved, and the prepared semiconductor nanoparticle can emit blue light in the (photo)luminescent wavelength range described herein with a relatively high efficiency, and an enhanced stability (e.g., atmospheric stability, etc.). Without wishing to be bound by a specific theory, this may suggest that the growth of particle may occur at the same crystal plane substantially without any defect. Surprisingly, the present inventors have found that as the semiconductor nanoparticle of an embodiment are disposed in the light emitting layer of the electroluminescent device, a combination of improved electroluminescent properties (e.g., a relatively high level maximum EQE and a relatively high level maximum luminance) can be achieved.

The zinc precursor may be a Zn metal powder, ZnO, an alkylated Zn compound (e.g., a C2 to C30 dialkyl zinc such as diethyl zinc), a Zn alkoxide (e.g., a zinc ethoxide), a Zn carboxylate (e.g., a zinc acetate), a Zn nitrate, a Zn perchlorate, a Zn sulfate, Zn acetylacetonate, a Zn halide (e.g., a zinc chloride), a Zn cyanide, a Zn hydroxide, a Zn carbonate, a Zn peroxide, or a combination thereof. Examples of the zinc precursor may be dimethyl zinc, diethyl zinc, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, or a combination thereof.

The selenium precursor may include selenium-trioctylphosphine (“Se-TOP”), selenium-tributylphosphine (“Se-TBP”), selenium-triphenylphosphine (“Se-TPP”), selenium-diphenylphosphine (“Se-DPP”), or a combination thereof, but is not limited thereto.

The tellurium precursor may include tellurium-tributylphosphine (“Te-TBP”), tellurium-triphenylphosphine (“Te-TPP”), tellurium-diphenylphosphine (“Te-DPP”), or a combination thereof, but is not limited thereto.

The sulfur precursor may be hexane thiol, octane thiol, decane thiol, dodecane thiol, hexadecane thiol, mercapto propyl silane, sulfur-trioctylphosphine (“S-TOP”), sulfur-tributylphosphine (“S-TBP”), sulfur-triphenylphosphine (“S-TPP”), sulfur-trioctylamine (“S-TOA”), a bis(trialkylsilyl) sulfide, a bis(trialkylsilylalkyl) sulfide e.g., bis(trimethylsilylmethyl) sulfide, ammonium sulfide, sodium sulfide, or a combination thereof.

The organic solvent may include a C6 to C22 primary amine such as hexadecylamine or oleyl amine, a C6 to C22 secondary amine such as dioctylamine, a C6 to C40 tertiary amine such as trioctylamine, a nitrogen-containing heterocyclic compound such as pyridine, a C6 to C40 olefin such as octadecene, a C6 to C40 aliphatic hydrocarbon such as hexadecane, octadecane, or squalane, an aromatic hydrocarbon substituted with a C6 to C30 alkyl group such as phenyldodecane, phenyltetradecane, or phenyl hexadecane, a primary, secondary, or tertiary phosphine substituted with a, e.g., at least one (e.g., 1, 2, or 3) C6 to C22 alkyl group (e.g., trioctylphosphine), a phosphine oxide substituted with a, e.g., at least one (e.g., 1, 2, or 3) C6 to C22 alkyl group (e.g., trioctyl phosphine oxide), a C12 to C22 aromatic ether such as phenyl ether or benzyl ether, or a combination thereof.

The semiconductor nanoparticles may have an organic ligand on a surface thereof. The organic ligand may coordinate, e.g., bind to, the surface of the produced nanocrystal and may have an effect on light emitting and electric characteristics and may effectively disperse the nanocrystal in an organic solvent. The organic ligand may include RCOOH, RNH₂, R₂NH, R₃N, RSH, RH₂PO, R₂HPO, R₃PO, RH₂P, R₂HP, R₃P, ROH, RCOOR′, RPO(OH)₂, R₂POOH, or a combination thereof, wherein, R and R′ independently are a substituted or unsubstituted C1 to C40 (e.g., C3 to C24) aliphatic hydrocarbon group, a substituted or unsubstituted C6 to C40 (e.g., C6 to C24) aromatic hydrocarbon group, or a combination thereof. One or more organic ligands may be used.

Examples of the organic ligand compound may include methane thiol, ethane thiol, propane thiol, butane thiol, pentane thiol, hexane thiol, octane thiol, dodecane thiol, hexadecane thiol, octadecane thiol, benzyl thiol; methane amine, ethane amine, propane amine, butane amine, pentane amine, hexane amine, octane amine, dodecane amine, hexadecyl amine, oleyl amine, octadecyl amine, dimethyl amine, diethyl amine, dipropyl amine; methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid, palmitic acid, or stearic acid; a phosphine such as methyl phosphine, ethyl phosphine, propyl phosphine, butyl phosphine, pentyl phosphine, tributyl phosphine, or trioctyl phosphine; a phosphine oxide compound such as methyl phosphine oxide, ethyl phosphine oxide, propyl phosphine oxide, butyl phosphine oxide, or trioctyl phosphine oxide; a diphenyl phosphine or triphenyl phosphine compound, or an oxide compound thereof; a C5 to C20 alkyl phosphonic acid; a C5 to C20 alkyl phosphinic acid such as hexylphosphinic acid, octylphosphinic acid, dodecanephosphinic acid, tetradecanephosphinic acid, hexadecanephosphinic acid, octadecanephosphinic acid; phosphonic acid; or the like, but are not limited thereto. One or more organic ligand compounds may be used. In an embodiment, the organic ligand compound may be a combination of RCOOH and an amine (e.g., RNH₂, R₂NH, R₃N, or a combination thereof) wherein, R is independently a substituted or unsubstituted C1 to C40 (C3-C24) aliphatic hydrocarbon group or a substituted or unsubstituted C6 to C40 (C6-C20) aromatic hydrocarbon group. In an embodiment R is independently a substituted or unsubstituted C1 to C40 (e.g., C3 to C24) aliphatic hydrocarbon group.

After completing the reaction, a nonsolvent is added to reaction products and nanocrystal particles coordinated with, e.g., bound to, the ligand compound may be separated. The nonsolvent may be a polar solvent that is miscible with the solvent used in the core formation reaction, shell formation reaction, or a combination thereof and is not capable of dispersing the produced nanocrystals therein. The nonsolvent may be selected taking into consideration the solvent used in the reaction and may be, for example, acetone, ethanol, butanol, isopropanol, ethanediol, water, tetrahydrofuran (“THF”), dimethyl sulfoxide (“DMSO”), diethyl ether, formaldehyde, acetaldehyde, a solvent having a similar solubility parameter to the foregoing non-solvents, or a combination thereof. The nanocrystal particles may be separated through centrifugation, sedimentation, chromatography, or distillation. The separated nanocrystals may be added to a washing solvent and washed, if desired. The washing solvent has no particular limit and may have a similar solubility parameter to that of the ligand and may include, for example, hexane, heptane, octane, chloroform, toluene, benzene, and the like.

The semiconductor nanoparticles of an embodiment may not be dispersible in water, any of the foregoing listed non-solvents, or a mixture thereof. The semiconductor nanoparticles of an embodiment may be water-insoluble.

The semiconductor nanoparticles of an embodiment may be dispersed in the aforementioned organic solvent. In an embodiment, the semiconductor nanoparticles may be dispersed in a C6 to C40 aliphatic hydrocarbon, a C6 to C40 aromatic hydrocarbon, or a mixture thereof.

In an electroluminescent device of an embodiment, a thickness of the light emitting layer may be selected appropriately. In an embodiment, the light emitting layer 3 or 30 may include a monolayer of semiconductor nanoparticles. In an embodiment, the light emitting layer 3 or 30 may include a monolayer of semiconductor nanoparticles, e.g., one or more, two or more, three or more, or four or more and 20 or less, 10 or less, 9 or less, 8 or less, 7 or less, or 6 or less, monolayers of semiconductor nanoparticles. The light emitting layer 3 or 30 may have a thickness of greater than or equal to about 5 nm, for example, greater than or equal to about 10 nm, greater than or equal to about 20 nm, or greater than or equal to about 30 nm and less than or equal to about 200 nm, for example, less than or equal to about 150 nm, less than or equal to about 100 nm, less than or equal to about 90 nm, less than or equal to about 80 nm, less than or equal to about 70 nm, less than or equal to about 60 nm, or less than or equal to about 50 nm. The light emitting layer 3 or 30 may have a thickness of, for example, about nm to about 150 nm, about 20 nm to about 100 nm, about 30 nm to about 50 nm, or a combination thereof.

The formation of the light emitting layer may be performed by preparing a composition including nanostructures (configured to emit a desired light) and applying or depositing the composition on a substrate, for example, including an electrode or a charge auxiliary layer in, e.g., by, an appropriate method (e.g., spin coating, inkjet printing, and the like).

In an embodiment, the emission layer may include a first layer including the semiconductor nanoparticle of an embodiment (hereinafter, referred to as “first semiconductor nanoparticle”) and a second layer being adjacent to the first layer and including a second semiconductor nanoparticle. Adjacent layers (e.g., the first emission layer and the second emission layer) in the multilayered emission layer may be configured to emit light of the same color (e.g., blue light). The second semiconductor nanoparticle may include a zinc chalcogenide, and the zinc chalcogenide may include zinc, selenium, and sulfur, and the semiconductor particles may emit blue light without including cadmium. The average particle size of the first semiconductor nanoparticles may be larger than the average particle size of the second semiconductor nanoparticles. A size (or an average size) of the second semiconductor nanoparticle may be greater than or equal to about 5 nm, greater than or equal to about 6 nm, greater than or equal to about 7 nm, greater than or equal to about 8 nm, greater than or equal to about 9 nm, greater than or equal to about 10 nm, or greater than or equal to about 10.5 nm. A size (or an average size) of the second semiconductor nanoparticle may be less than or equal to about 12 nm, less than or equal to about 11.8 nm, less than or equal to about 11.6 nm, less than or equal to about 11.4 nm, less than or equal to about 11.2 nm, less than or equal to about 11 nm, less than or equal to about 10.8 nm, less than or equal to about 10.6 nm, less than or equal to about 10.4 nm, or less than or equal to about 10 nm.

In an embodiment, the first emission layer may be disposed between the first electrode (e.g., the anode) and the second emission layer. In an embodiment, the second emission layer may be disposed between the first electrode and the first emission layer. The manufacture of the second semiconductor nanoparticle is not particularly limited and can be selected appropriately. In an embodiment, the manufacture of the second semiconductor nanoparticles may be performed without the use of the additive. In an embodiment, the manufacture of the second semiconductor nanoparticle may be performed at a lower shell formation reaction temperature than the first semiconductor nanoparticle. Other details described in relation to the manufacture of the first semiconductor nanoparticle herein can be applied to, e.g., used in, the manufacture of the second semiconductor nanoparticle.

The first semiconductor nanoparticles and the second semiconductor nanoparticles may have the same or different peak emission wavelengths. A difference in the peak emission wavelength between the first semiconductor nanoparticle and the second semiconductor nanoparticle may be less than or equal to about 10 nm, less than or equal to about 7 nm, less than or equal to about 5 nm, or less than or equal to about 3 nm. In an embodiment, both the first layer and the second layer may emit blue light.

The formation of the multilayered emission layer may include forming a layer of (first or second) semiconductor nanoparticles and exchanging ligands of particles contained in the layer formed by contacting the formed layer with, for example, a metal halide (e.g., zinc chloride) organic solution (e.g., an alcohol solution). Alternatively, the formation of the multilayered emission layer may include dispersing (first or second) semiconductor nanoparticles in an organic solvent to obtain ligand-exchanged particles by adding a metal halide (e.g., zinc chloride) organic solution (e.g., an alcohol solution) thereto, and forming a first layer (or second layer) therefrom. On the ligand-exchanged layer, a layer of semiconductor nanoparticles may be further provided. Accordingly, adjacent layers (e.g., the first emission layer and the second emission layer) in the multilayer structure may have the same or different compositions or the same or different ligands. In an embodiment, the emission layer or the multilayer emission layers may exhibit a halogen amount that changes in a thickness direction. In the (multi-layered) emission layer of an embodiment, the halogen amount may increase toward the electron auxiliary layer. In the (multi-layered) emission layer of one embodiment, the organic ligand amount may decrease toward the electron auxiliary layer. In the emission layer of an embodiment, the halogen amount may decrease toward the electron auxiliary layer. In the (multilayered) emission layer of an embodiment, the organic ligand amount may increase toward the electron auxiliary layer.

The electroluminescent device may further include a charge (hole or electron) auxiliary layer between the first electrode and the second electrode (e.g., an anode and a cathode). In an embodiment, the electroluminescent device may include a hole auxiliary layer 20 or an electron auxiliary layer 40 between the anode 10 and the light emitting layer 30, between the cathode 50 and the light emitting layer 30, or a combination thereof. (See FIGS. 2 and 3).

The light emitting device according to an embodiment may further include a hole auxiliary layer. The hole auxiliary layer 20 may be disposed between the first electrode 10 and the light emitting layer 30. The hole auxiliary layer 20 may include a hole injection layer, a hole transport layer, an electron blocking layer, or a combination thereof. The hole auxiliary layer 20 may be a layer of a single component or a multilayer structure in which adjacent layers include different components.

The hole auxiliary layer 20 may have a HOMO energy level that can be matched with the HOMO energy level of the light emitting layer 30 in order to enhance mobility of holes transferred from the hole auxiliary layer 20 to the light emitting layer 30. In an embodiment, the hole auxiliary layer 20 may include a hole injection layer close to the first electrode 10 and a hole transport layer close to the light emitting layer 30.

The material included in the hole auxiliary layer 20 (e.g., a hole transport layer, a hole injection layer, or an electron blocking layer) is not particularly limited, and may include, for example, poly(9,9-dioctyl-fluorene-co-N-(4)-butylphenyl)-diphenylamine) (“TFB”), polyarylamine, poly(N-vinylcarbazole), poly(3,4-ethylenedioxythiophene) (“PEDOT”), poly(3,4-ethylenedioxythiophene):polystyrene sulfonate (“PEDOT:PSS”), polyaniline, polypyrrole, N,N,N′,N′-tetrakis(4-methoxyphenyl)-benzidine (“TPD”), 4,4′-bis[N-(1-naphthyl)-N-phenyl-amino]biphenyl (“α-NPD”), 4,4′,4″-Tris[phenyl(m-tolyl)amino]triphenylamine (m-MTDATA), 4,4′,4″-tris(N-carbazolyl)-triphenylamine (“TCTA”), 1,1-bis[(di-4-toylamino)phenyl]cyclohexane (“TAPC”), a p-type metal oxide (e.g., NiO, WO₃, MoO₃, etc.), a carbon-based material such as graphene oxide, or a combination thereof, but is not limited thereto.

In the hole auxiliary layer(s), the thickness of each layer may be appropriately selected. For example, the thickness of each layer may be greater than or equal to about 5 nm, greater than or equal to about 10 nm, greater than or equal to about 15 nm, or greater than or equal to about 20 nm and less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 35 nm, or less than or equal to about 30 nm, but is not limited thereto.

The electron auxiliary layer 40 may be disposed between the light emitting layer 30 and the second electrode 50. The electron auxiliary layer 40 may include, for example, an electron injection layer, an electron transport layer, a hole blocking layer, or a combination thereof. The electron auxiliary layer may include, for example, an electron injection layer (“EIL”) that facilitates injection of electrons, an electron transport layer (“ETL”) that facilitates transport of electrons, a hole blocking layer (“HBL”) that blocks the movement of holes, or a combination thereof.

In an embodiment, the electron injection layer may be disposed between the electron transport layer and the cathode. For example, the hole blocking layer may be disposed between the light emitting layer and the electron transport (injection) layer but is not limited thereto. The thickness of each layer may be selected appropriately. For example, the thickness of each layer may be greater than or equal to about 1 nm and less than or equal to about 500 nm, but is not limited thereto. The electron injection layer may be an organic layer formed by vapor deposition. The electron transport layer may include an inorganic oxide nanoparticle or may be an organic layer formed by vapor deposition.

The electron transport layer (“ETL”), the electron injection layer, the hole blocking layer, or a combination thereof may include, for example, 1,4,5,8-naphthalene-tetracarboxylic dianhydride (“NTCDA”), bathocuproine (“BCP”), tris[3-(3-pyridyl)-mesityl]borane (“3TPYMB”), LiF, tris(8-hydroxyquinoline)aluminum (“Alq₃”), tris(8-hydroxyquinoline)gallium (“Gaq₃”), tris-(8-hydroxyquinoline)indium (“Inq₃”), bis(8-hydroxyquinoline)zinc (“Znq₂”), bis(2-(2-hydroxyphenyl)benzothiazolate)zinc (“Zn(BTZ)₂”), bis(10-hydroxybenzo[h]quinolinato)beryllium (“BeBq₂”), 8-(4-(4,6-di(naphthalen-2-yl)-1,3,5-triazin-2-yl)phenyl)quinolone (“ET204”), 8-hydroxyquinolinato lithium (“Liq”), an n-type metal oxide (e.g., ZnO, HfO₂, etc.) or a combination thereof, but is not limited thereto.

The electron auxiliary layer 40 may include an electron transport layer. The electron transport layer may include a plurality of nanoparticles. The plurality of nanoparticles may include a metal oxide containing zinc.

The metal oxide may include zinc oxide, zinc magnesium oxide, or a combination thereof. The metal oxide may include Zn₁₋ₓ MₓO, wherein M is Mg, Ca, Zr, W, Li, Ti, Y, Al, or a combination thereof and 0≤×≤0.5. In an embodiment, the M in the formula Zn₁₋ₓ MₓO may be magnesium (Mg). In an embodiment, in the formula Zn₁₋ₓ MₓO, the x may be greater than or equal to about 0.01 and less than or equal to about 0.3, for example, less than or equal to about 0.25, less than or equal to about 0.2, or less than or equal to about 0.15.

The absolute value of the LUMO of the aforementioned nanostructures included in the light emitting layer may be greater or smaller than the absolute value of the LUMO of the metal oxide. The average size of the nanoparticles may be greater than or equal to about 1 nm, for example, greater than or equal to about 1.5 nm, greater than or equal to about 2 nm, greater than or equal to about 2.5 nm, or greater than or equal to about 3 nm and less than or equal to about 10 nm, less than or equal to about 9 nm, less than or equal to about 8 nm, less than or equal to about 7 nm, less than or equal to about 6 nm, or less than or equal to about 5 nm.

In an embodiment, each thickness of the electron auxiliary layer 40 (e.g., electron injection layer, electron transport layer, or hole blocking layer) may be greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, or greater than or equal to about 20 nm, and less than or equal to about 120 nm, less than or equal to about 110 nm, less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 30 nm, or less than or equal to about 25 nm, but is not limited thereto.

A device according to an embodiment may have a normal structure. In an embodiment, in the device, the anode 10 disposed on the transparent substrate 100 may include a metal oxide-based transparent electrode (e.g., an ITO electrode), and the cathode 50 facing the anode 10 may include a conductive metal (e.g., having a relatively low work function, such as Mg, Al, etc.). The hole auxiliary layer 20 (e.g., a hole injection layer such as PEDOT:PSS, p-type metal oxide, or a combination thereof; a hole transport layer such as TFB, polyvinylcarbazole (“PVK”), or a combination thereof; or a combination thereof) may be provided between the transparent electrode 10 and the light emitting layer 30. The hole injection layer may be disposed close to the transparent electrode and the hole transport layer may be disposed close to the light emitting layer. The electron auxiliary layer 40 such as an electron injection/transport layer may be disposed between the light emitting layer 30 and the cathode 50. see FIG. 2

A device according to an embodiment may have an inverted structure. Herein, the cathode 50 disposed on the transparent substrate 100 may include a metal oxide-based transparent electrode (e.g., ITO), and the anode 10 facing the cathode may include a metal (e.g., having a relatively high work function, Au, Ag, etc.). For example, an (optionally doped) n-type metal oxide (crystalline Zn metal oxide) or the like may be disposed as an electron auxiliary layer 40 (e.g., an electron transport layer) between the transparent electrode 50 and the light emitting layer 30. a hole auxiliary layer 20 (e.g., a hole transport layer including TFB, PVK, or a combination thereof; a hole injection layer including MoO₃ or other p-type metal oxide; or a combination thereof) may be disposed between the metal anode 10 and the light emitting layer 30. (See FIG. 3).

The aforementioned device may be manufactured by an appropriate method. For example, the electroluminescent device may be manufactured by optionally forming a hole auxiliary layer (e.g., by deposition or coating) on a substrate on which an electrode is disposed, forming a light emitting layer including nanostructures (e.g., a pattern of the aforementioned nanostructures), and forming (optionally, an electron auxiliary layer and) an electrode (e.g., by vapor deposition or coating) on the light emitting layer. A method of forming the electrode/hole auxiliary layer/electron auxiliary layer may be appropriately selected and is not particularly limited.

The electroluminescent device of an embodiment may be configured to emit blue light. A wavelength range of the blue light may be the same as described herein.

In the electroluminescent device of an embodiment, a maximum external quantum efficiency (“EQE”) may be greater than or equal to about 4%, greater than or equal to about 5%, greater than or equal to about 6%, greater than or equal to about 7%, greater than or equal to about 8%, greater than or equal to about 9%, greater than or equal to about 10%, greater than or equal to about 10.5%, greater than or equal to about 11%, greater than or equal to about 11.5%, greater than or equal to about 12%, greater than or equal to about 12.5%, greater than or equal to about 13%, greater than or equal to about 13.5%, or greater than or equal to about 14%. In the electroluminescent device of an embodiment, a maximum external quantum efficiency (“EQE”) may be less than or equal to about 50%, less than or equal to about 40%, less than or equal to about 30%, or less than or equal to about 20%.

In an embodiment, the light emitting device may exhibit a maximum luminance of greater than or equal to about 88,000 nit (cd/m²), greater than or equal to about 90,000 nit, greater than or equal to about 95,000 nit, greater than or equal to about 100,000 nit, greater than or equal to about 105,000 nit, greater than or equal to about 110,000 nit, greater than or equal to about 115,000 nit, greater than or equal to about 120,000 nit, or greater than or equal to about 125,000 nit. The light emitting device may exhibit a (maximum) luminance of greater than or equal to about 3,000 nit to about 500,000 nit.

In an embodiment, the electroluminescent device may exhibit an improved life-span. In an embodiment, the life span of the electroluminescent device may be measured by driving the device at a predetermined initial luminance (for example, about 100 nit to about 3,000 nit, about 200 nit to about 2,800 nit, about 400 nit to about 2,600 nit, about 600 nit to about 2,500 nit, about 650 nit to about 2,000 nit, or a combination thereof).

In an embodiment, the life span, T50 of the device may be greater than or equal to about 150 hours, greater than or equal to about 300 hours, greater than or equal to about 310 hours, greater than or equal to about 350 hours, greater than or equal to about 380 hours, greater than or equal to about 400 hours, greater than or equal to about 450 hours, or greater than or equal to about 500 hours.

In an embodiment, the life span, T90 of the device may be greater than or equal to about 50 hours, greater than or equal to about 75 hours, greater than or equal to about 100 hours, greater than or equal to about 125 hours, greater than or equal to about 150 hours, greater than or equal to about 175 hours, or greater than or equal to about 200 hours.

In an embodiment, the life span, the T50 of the device may be from about 150 hours to about 5,000 hours, from about 400 hours to about 4,000 hours, from about 500 hours to about 3,500 hours, from about 750 hours to about 2,000 hours, from about 1,000 hours to about 1,500 hours, or a combination thereof.

In an embodiment, the life span, the T90 of the device may be about 30 hours to about 2,500 hours, about 45 hours to about 2,000 hours, about 50 hours to about 1,500 hours, about 75 hours to about 1,000 hours, about 100 hours to about 800 hours, about 150 hours to about 700 hours, about 200 hours to about 500 hours, about 300 hours to about 400 hours, or a combination thereof.

In an embodiment, a display device including the electroluminescent device described herein.

The display device may include a first pixel and a second pixel that is configured to emit light different from the first pixel. The first pixel, the second pixel, or a combination thereof may include the electroluminescent device of an embodiment.

The display device or an electronic device may include (or may be) a handheld terminal, a monitor, a notebook computer, a television, an electronic display board, a camera, or a part for, e.g., of, an automatic, e.g., autonomous, vehicle.

Hereinafter, an embodiment is illustrated in more detail with reference to examples. However, these examples are exemplary, and the present scope is not limited thereto.

### Examples

### Analysis Method

1. Photoluminescence Analysis and Absolute Quantum Yield

Photoluminescence (“PL”) spectra of the nanoparticles are measured at room temperature using a Hitachi F-7000 spectrophotometer with an irradiation wavelength of 400 nanometers (nm). An absolute QY is measured by using a Quantaurus-QY measurement equipment (Quantaurus-QY Absolute PL quantum yield spectrophotometer C11347-11) from Hamamatsu Co., Ltd.
2. Transmission Electron Microscopy (“TEM”) Analysis

Transmission electron micrographs of nanoparticles manufactured are obtained using UTF30 Tecnai electron microscope.

Measurement of the shape factor of the particle using the image J program (smoothing twice) for the obtained TEM picture is also conducted.
3. Inductively Coupled Plasma Atomic emission spectroscopy (“ICP-AES”) Analysis

An inductively coupled plasma-atomic emission spectroscopy (“ICP-AES”) analysis is performed using Shimadzu ICPS-8100.
4. Electroluminescence Spectroscopic Analysis

A current depending on a voltage is measured using a Keithley 2635B source meter while applying a voltage and electroluminescent (“EL”) light emitting luminance is measured using a CS2000 spectrometer.

Synthesis is performed under an inert gas atmosphere (nitrogen flowing condition) unless particularly mentioned.

### Preparation Example 1

A 2 molar (moles per liter (M)) Se/TOP stock solution, a 1 M S/TOP stock solution, and a 0.1 M Te/TOP stock solution are prepared by dispersing selenium (Se), sulfur(S), and tellurium (Te) in trioctylphosphine (TOP), respectively.

In a 300 milliliter (mL) reactor containing trioctylamine, 4.5 millimoles (mmol) of zinc acetate is added to the reactor with oleic acid and heated at 120° C. under vacuum. After 1 hour, nitrogen is introduced into the reactor.

The reactor is heated to 300° C., and the Se/TOP stock solution and the Te/TOP stock solution in a Te:Se mole ratio of 1/20 are rapidly injected into the reactor. When the reaction is complete, the reaction solution is rapidly cooled to room temperature and ethanol is added to the reactor. The reaction product mixture is centrifuged and the formed precipitate is separated and dispersed in hexane to obtain a ZnSeTe core. An average size of the cores is about 3 nm.

Zinc acetate and oleic acid are added to a flask containing trioctylamine and the obtained mixture is heated at 120° C. under vacuum. Nitrogen (N₂) is then introduced into the reactor, and during the time when the mixture is heated to 340° C., a hexane dispersion of the obtained ZnTeSe cores is added quickly. Subsequently, the Se/TOP stock solution together with an additional zinc precursor (a zinc oleate) is added to the reactor and a reaction proceeds. The Se/TOP stock solution is divided into five portions and added in 5 additions. During the addition of the Se precursor, an alkali metal compound (a sodium oleate) is added twice. Subsequently, an S/TOP stock solution is added to the reactor together with an additional zinc precursor (a zinc oleate) and an additional reaction proceeds, and an alkali metal compound (a sodium oleate), a zinc chloride, and aluminum chloride are added during the additional reaction, respectively. The total reaction time is 180 minutes.

Regarding the ZnSe shell formation, the amount of the selenium precursor used per 1 mole of the zinc precursor is 0.67 moles, and regarding the ZnS shell formation, the amount of sulfur precursor used per 1 mole of zinc precursor is 1.38 moles.

The amount of alkali metal compound used per 1 mole of the selenium is 0.06 moles, and the amount of the zinc chloride, the alkali metal compound, and aluminum chloride used per mole of the sulfur precursor is 0.05 moles, respectively.

A thickness of the ZnSe shell is about 4.1 nm and a thickness of the ZnS shell layer is about 0.7 nm. The semiconductor nanoparticle has an average solidity of about 0.94.

When the reaction is complete, the reactor is cooled to room temperature and is added with ethanol to facilitate precipitation of the nanoparticles, which are separated by centrifuge to recover. Then, the obtained nanoparticles are dispersed in octane.

For the semiconductor nanoparticle thus obtained, a photoluminescent spectroscopy analysis is carried out and the results are shown in Table 1.

For the nanoparticles thus obtained, a TEM analysis, and an ICP-AES analysis are carried out and the results are shown in Table 1, Table 2, and Table 3.

### Preparation Example 2

Semiconductor nanoparticles are prepared in the same manner as in Preparation Example 1, except that aluminum chloride is not used.

Photoluminescence spectroscopy analysis is conducted for the prepared semiconductor nanoparticles, and the results are summarized in Table 1.

### Preparation Example 3

Semiconductor nanoparticles are prepared in the same manner as in Preparation Example 1, except that the amount of the Se precursor is 0.67 moles per mole of the zinc precursor, the Se precursor is divided into 9 portions, intermittently injected in 9 injections, and the injection amount and number of injections of zinc chloride are doubled.

Photoluminescence spectroscopy analysis is conducted for the prepared semiconductor nanoparticles, and the results are summarized in Table 1.

### Preparation Example 4

Semiconductor nanoparticles are prepared in the same manner as in Preparation Example 1, except that with regard to ZnSe shell formation, the amount of the Se precursor is 0.67 moles per mole of the zinc precursor and the Se precursor is divided into 9 portions and intermittently injected in 9 injections.

Photoluminescence spectroscopy analysis and the transmission electron microscope analysis are conducted for the prepared semiconductor nanoparticles, and the results are summarized in Tables 1 and 2.

A thickness of the ZnSe shell is about 4.6 nm and a thickness of the ZnS shell layer is about 0.8 nm. The semiconductor nanoparticle has an average solidity of about 0.93,

### Comparative Preparation Example 1

Semiconductor nanoparticles are prepared in the same manner as in Preparation Example 1, except that the alkali metal compound, the zinc chloride, and the aluminum chloride are not used.

Photoluminescence spectroscopy analysis and the transmission electron microscope analysis are conducted for the prepared semiconductor nanoparticles, and the results are summarized in Tables 1 and 2.

### Comparative Preparation Example 2

Semiconductor nanoparticles are prepared in the same manner as in Preparation Example 4, except that the alkali metal compound, the zinc chloride, and the aluminum chloride are not used.

Photoluminescence spectroscopy analysis and the transmission electron microscope analysis are conducted for the prepared semiconductor nanoparticles, and the results are summarized in Tables 1 and 2.

TABLE 1

| | PWL (nm) | Abs QY | FWHM (nm) |
|---|---|---|---|
| Prep. Example 1 | 467 | 90% | 40 |
| Prep. Example 2 | 468 | 94% | 40 |
| Prep. Example 3 | 469 | 82% | 45 |
| Prep. Example 4 | 468 | 84% | 43 |
| Comp. Prep. Example 1 | 463 | about 79% | 48 |
| Comp. Prep. Example 2 | 470 | 73% | 50 |

PWL: peak emission wavelength
Abs QY: Absolution quantum yield
FWHM: full width at half maximum

TABLE 2

| | Avg. dia. and std | Aspect Ratio | Circularity |
|---|---|---|---|
| Prep. Example 1 | 12.9 +/− 0.9 nm | 1.14:1 | 0.77 |
| Prep. Example 4 | 14.3 +/− 1.1 nm | 1.13:1 | 0.74 |
| Comp. Prep. Example 1 | 13.1 +/− 1.1 nm | 1.19:1 | 0.79 |
| Comp. Prep. Example 2 | 14.0 +/− 1.4 nm | 1.21:1 | 0.74 |

Avg. dia. and std: Average particle diameter and standard deviation

TABLE 3

| | Te:Se | Te:S | Se:(S + Se) | (S + Se):Zn | Te:Zn | Se:Zn | S:Zn |
|---|---|---|---|---|---|---|---|
| Prep. Example | 0.007:1 | 0.01:1 | 0.5932:1 | 0.8973:1 | 0.0038:1 | 0.5323:1 | 0.365:1 |
| 1 | | | | | | | |

From the results of Table 1, it is confirmed that the semiconductor nanoparticles of Examples may exhibit improved luminescent properties compared to Comparative Examples.

The results of Tables 1 and 2 confirm that the semiconductor nanoparticles of the Examples have sizes, and shapes different from those of the semiconductor nanoparticles prepared in Comparative Examples.

### Device Example 1

The electroluminescent device having the structure of indium tin oxide (ITO)/poly(3,4-ethylenedioxythiophene):polystyrene sulfonate (PEDOT:PSS) (300 angstroms)/poly[(9,9-dioctylfluorene-co-(4,4′-(N-4-butylphenyl)diphenylamine] (TFB) (250 angstroms)/light emitting layer of semiconductor nanoparticles (360 angstroms)/ZnMgO (240 angstroms)/Al electrode is fabricated using the semiconductor nanoparticle of Preparation Example 1 according to the following method:

On an indium tin oxide (ITO) (anode)-deposited glass substrate, a poly(3,4-ethylenedioxythiophene):polystyrene sulfonate (PEDOT:PSS) solution (H. C. Starks) and poly[(9,9-dioctylfluorene-co-(4,4′-(N-4-butylphenyl)diphenylamine] solution (TFB) (Sumitomo) are spin-coated and then heat-treated as a hole injecting layer (HIL) and a hole transporting layer (“HTL”) with a thickness of 30 nm and a thickness of 25 nm, respectively. The semiconductor nanoparticles obtained from Preparation Example 1 are dispersed in octane and is spin-coated on the HTL and heat-treated to provide a light emitting film with a thickness of 36 nm. On the light-emitting film is formed an electron transporting layer (“ETL”) including zinc oxide nanoparticles and then an aluminum (AI) is vacuum-deposited on the ETL to provide a second electrically conducting layer.

The electroluminescent properties of the obtained device are evaluated, and the results are shown in Table 4. The manufactured device has a T50 of greater than or equal to 300 hours and T90 of greater than or equal to 100 hours.

TABLE 4

| | | Maximum Luminance |
|---|---|---|
| | Maximum External | (Lum Max) (nit |
| | Quantum Efficiency | (candelas per |
| | (EQE Max) (%) | square meter)) |
| Device Example 1 | 12 | 101,756 |

### Device Comparative Example 1

Except for using the semiconductor nanoparticles manufactured in Comparative Example 1, a device is manufactured in the same manner as in Example 1. The electroluminescence properties and lifespan of the manufactured device of the manufactured device are measured, and it is confirmed that the maximum external quantum efficiency is less than 9% and the maximum luminance is less than 90,000 nit.

While this disclosure has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

What is claimed is:

1. Semiconductor nanoparticles comprising zinc, selenium, and sulfur:
wherein the semiconductor nanoparticles comprise a zinc chalcogenide,
wherein the semiconductor nanoparticles do not comprise cadmium,
the semiconductor nanoparticles exhibit a peak emission wavelength of greater than or equal to about 455 nanometers and less than or equal to about 480 nanometers,
in a photoluminescence spectroscopy analysis, the semiconductor nanoparticles exhibit an absolute quantum yield of greater than or equal to about 80% and a full width at half maximum of less than or equal to about 50 nanometers, and
an average particle size of the semiconductor nanoparticles is greater than or equal to about 12 nanometers and less than or equal to about 50 nanometers.

2. The semiconductor nanoparticles of claim 1, wherein the peak emission wavelength is greater than or equal to about 458 nanometers and less than or equal to about 478 nanometers.

3. The semiconductor nanoparticles of claim 1, wherein the average particle size of the semiconductor nanoparticles is greater than or equal to about 12 nanometers and less than or equal to about 14 nanometers and the absolute quantum yield is greater than or equal to about 90%; or
wherein the average particle size of the semiconductor nanoparticles is greater than 14 nanometers and the absolute quantum yield is greater than or equal to about 80%.

4. The semiconductor nanoparticles of claim 1, wherein in the semiconductor nanoparticles, a mole ratio of selenium to a sum of selenium and sulfur is greater than or equal to about 0.57:1 and less than or equal to about 0.99:1.

5. The semiconductor nanoparticles of claim 1, wherein the zinc chalcogenide further comprises tellurium and in the semiconductor nanoparticles, a mole ratio of tellurium to sulfur is greater than or equal to about 0.008:1 and less than or equal to about 0.05:1.

6. The semiconductor nanoparticles of claim 1, wherein the semiconductor nanoparticles further comprise aluminum and an alkali metal.

7. The semiconductor nanoparticles of claim 1, wherein an average aspect ratio of the semiconductor nanoparticles is less than or equal to about 1.15:1.

8. The semiconductor nanoparticles of claim 1, wherein the semiconductor nanoparticles have a core shell structure, and the core shell structure comprises a core comprising a first semiconductor nanocrystal and a semiconductor nanocrystal shell disposed on the core,
wherein the first semiconductor nanocrystal comprises a first zinc chalcogenide comprising zinc, selenium, and tellurium,
wherein the semiconductor nanocrystal shell comprises a second semiconductor nanocrystal comprising a second zinc chalcogenide comprising zinc and selenium and a third semiconductor nanocrystal comprising a third zinc chalcogenide comprising zinc and sulfur,
wherein a thickness of the second semiconductor nanocrystal is greater than or equal to about 3.5 nanometers, and
optionally wherein a thickness of the third semiconductor nanocrystal is less than or equal to about 1 nanometer.

9. A method of producing the semiconductor nanoparticles of claim 1, the method comprising:
contacting a zinc precursor and a chalcogen precursor at a reaction temperature in the presence of a first semiconductor nanocrystal comprising a first zinc chalcogenide to prepare a semiconductor nanocrystal shell,
wherein the chalcogen precursor comprises a selenium precursor, a sulfur precursor, or a combination thereof, and
wherein a reaction of the zinc precursor and the chalcogen precursor is carried out in the presence of an additive, wherein the additive comprises an alkali metal compound and a metal chloride, and the metal chloride comprises a zinc chloride, an aluminum chloride, or a combination thereof.

10. The method of claim 9, wherein the alkali metal compound comprises an alkali metal fatty acid salt, and the metal chloride comprises a zinc chloride and an aluminum chloride.

11. The method of claim 9, wherein the additive is added at the same time as an addition of the selenium precursor or after an addition of the selenium precursor.

12. An electroluminescent device comprising:
a first electrode and a second electrode spaced apart from each other, and
an emission layer disposed between the first electrode and the second electrode, the emission layer comprising a first semiconductor nanoparticle comprising zinc, selenium, and sulfur,
wherein the first semiconductor nanoparticle comprises a zinc chalcogenide;
wherein the first semiconductor nanoparticle does not comprise cadmium,
wherein the first semiconductor nanoparticle has a particle size of greater than or equal to about 12 nanometers and less than or equal to about 50 nanometers, and
wherein the electroluminescent device is configured to emit blue light, and the electroluminescent device exhibits a maximum external quantum efficiency of greater than or equal to about 10% and a maximum luminance of greater than or equal to about 100,000 candelas per square meter.

13. The electroluminescent device of claim 12, wherein the emission layer is configured to exhibit a peak emission wavelength of greater than or equal to about 458 nanometers and less than or equal to about 478 nanometers, as being irradiated with incident light.

14. The electroluminescent device of claim 12, wherein the first semiconductor nanoparticle has a size of greater than or equal to about 12.5 nanometers and less than or equal to about 50 nanometers.

15. The electroluminescent device of claim 12, wherein in the first semiconductor nanoparticle, a mole ratio of selenium to a sum of selenium and sulfur is greater than or equal to about 0.57:1 and less than or equal to about 0.99:1.

16. The electroluminescent device of claim 12, wherein the zinc chalcogenide further comprises tellurium and in the first semiconductor nanoparticles, a mole ratio of tellurium to sulfur is greater than or equal to about 0.008:1 and less than or equal to about 0.05:1.

17. The electroluminescent device of claim 12, wherein the first semiconductor nanoparticles further comprise aluminum and an alkali metal.

18. The electroluminescent device of claim 12, wherein the light emitting layer comprises a first light emitting layer and a second light emitting layer disposed between the first light emitting layer and the first electrode, the first light emitting layer comprises the first semiconductor nanoparticle, the second light emitting layer comprises a second semiconductor nanoparticle comprising a zinc chalcogenide and comprising zinc, selenium, and sulfur, and a particle size of the first semiconductor nanoparticle is greater than a particle size of the second semiconductor nanoparticle.

19. A display device comprising the electroluminescent device of claim 12.

20. A semiconductor nanoparticle comprising:
a core comprising a first semiconductor nanocrystal comprising a first zinc chalcogenide comprising zinc, selenium, and tellurium; and
a semiconductor nanocrystal shell comprising
a middle shell layer comprising a second semiconductor nanocrystal comprising a second zinc chalcogenide comprising zinc and selenium disposed on the core, and
an outer shell layer comprising a third semiconductor nanocrystal comprising a third zinc chalcogenide comprising zinc and sulfur disposed on the middle shell layer,
wherein a particle size of the semiconductor nanoparticle is greater than or equal to about 12 nanometers and less than or equal to about 50 nanometers,
wherein a thickness of the second semiconductor nanocrystal is greater than or equal to about 3.5 nanometers,
wherein a thickness of the third semiconductor nanocrystal is less than or equal to about 1 nanometer, and
wherein an aspect ratio of the semiconductor nanoparticle is less than or equal to about 1.15:1.
